(19) United States
(12) Patent Application Publication
(10) Pub. No.: US 2025/0140316 A1
(43) Pub. Date: May 1, 2025

(54) SEMICONDUCTOR DEVICE WITH MEMORY STRING

(71) Applicant: SAMSUNG ELECTRONICS CO., LTD., Suwon-si (KR)

(72) Inventor: Kwangsoo Kim, Suwon-si (KR)

(21) Appl. No.: 18/909,041

(22) Filed: Oct. 8, 2024

(30) Foreign Application Priority Data
Nov. 1, 2023 (KR) 10-2023-0149280

(51) Int. Cl. G11C 16/04; H01L 25/065; H10B 41/10; H10B 41/27; H10B 41/35; H10B 41/41; H10B 43/10; H10B 43/27; H10B 43/35; H10B 43/40; H10B 80/00

(52) U.S. Cl. CPC G11C 16/0483; H01L 25/0657; H10B 41/10; H10B 41/27; H10B 41/35; H10B 41/41; H10B 43/10; H10B 43/27; H10B 43/35; H10B 43/40; H10B 80/00; H01L 2225/06506

(57) ABSTRACT

A semiconductor device includes a peripheral circuit structure and a cell structure stacked on the peripheral circuit structure, the cell structure including gate electrodes spaced apart from each other in a vertical direction, a channel structure arranged within a channel hole extending in the vertical direction by passing through the gate electrodes, including a channel layer and a back gate electrode spaced apart from the channel layer, and including a first end portion arranged adjacent to the peripheral circuit structure and a second end portion opposite to the first end portion, a common source layer connected to the channel layer at the second end portion of the channel structure, an upper insulating layer on the common source layer, and a back gate contact arranged within a first backside contact hole passing through the upper insulating layer and the common source layer and connected to the back gate electrode.

### CROSS-REFERENCE TO RELATED APPLICATION

This application claims priority under 35 U.S.C. § 119 to Korean Patent Application No. 10-2023-0149280, filed on Nov. 1, 2023, in the Korean Intellectual Property Office, the disclosure of which is incorporated by reference herein in its entirety.

### BACKGROUND

Semiconductor devices capable of storing high-capacity data are used in electronic systems having data storage. In one method of increasing data storage capacity of semiconductor devices, semiconductor devices include three-dimensionally arranged memory cells instead of two-dimensionally arranged memory cells. In addition, in some semiconductor devices, portions of the semiconductor devices are formed on first substrates, other portions of the semiconductor devices are formed on second substrates, and the first substrates and the second substrates are bonded to each other.

### SUMMARY

The present disclosure relates to a semiconductor device, and more particularly, to a semiconductor device having a memory string arranged in a vertical direction. The present disclosure provides a semiconductor device having high operating characteristics and improved integration.

According to an aspect of the present disclosure, a semiconductor device includes: a peripheral circuit structure and a cell structure stacked on the peripheral circuit structure, wherein the cell structure includes gate electrodes spaced apart from each other in a vertical direction, a channel structure arranged within a channel hole extending in the vertical direction by passing through the gate electrodes, including a channel layer and a back gate electrode spaced apart from the channel layer, and including a first end portion arranged adjacent to the peripheral circuit structure and a second end portion opposite to the first end portion, a common source layer arranged to be connected to the channel layer at the second end portion of the channel structure, an upper insulating layer on the common source layer, and a back gate contact arranged within a first backside contact hole passing through the upper insulating layer and the common source layer and connected to the back gate electrode.

According to another aspect of the present disclosure, a semiconductor device includes: a peripheral circuit structure and a cell structure stacked on the peripheral circuit structure, wherein the cell structure includes gate electrodes spaced apart from each other in a vertical direction, a channel structure arranged within a channel hole extending in the vertical direction by passing through the gate electrodes, including a channel layer and a back gate electrode spaced apart from the channel layer, and including a first end portion arranged adjacent to the peripheral circuit structure and a second end portion opposite to the first end portion, a bit line arranged adjacent to the first end portion of the channel structure and electrically connected to the channel layer, a common source layer arranged adjacent to the second end portion of the channel structure and connected to the channel layer, a back gate contact arranged adjacent to the second end portion of the channel structure and connected to the back gate electrode, and a first backside wiring layer arranged on the back gate contact and electrically connected to the back gate contact.

According to another aspect of the present disclosure, a semiconductor device includes: a peripheral circuit structure comprising a substrate and a peripheral circuit transistor arranged on the substrate, gate electrodes spaced apart from each other in a vertical direction on the peripheral circuit structure, a channel layer arranged within a channel hole extending in the vertical direction by passing through the gate electrodes, a back gate electrode arranged within the channel hole and electrically insulated from the channel layer by an insulating liner, a bit line arranged adjacent to a first end portion of the channel layer and electrically connected to the channel layer, a common source layer arranged adjacent to a second end portion opposite to the first end portion of the channel layer and connected to the channel layer, an upper insulating layer on the common source layer, a back gate contact arranged adjacent to the second end portion of the channel layer and connected to the back gate electrode by passing through the upper insulating layer and the common source layer, a common source contact connected to the common source layer by passing through the upper insulating layer, a first spacer arranged between the upper insulating layer and the back gate contact and between the common source layer and the back gate contact, a second spacer arranged between the upper insulating layer and the common source contact, a first backside wiring layer arranged on the upper insulating layer and electrically connected to the back gate contact, and a second backside wiring layer spaced apart from the first backside wiring layer on the upper insulating layer and electrically connected to the common source contact.

### BRIEF DESCRIPTION OF THE DRAWINGS

FIG. 1 is a block diagram of an example of a semiconductor device.

FIG. 2 is a circuit diagram illustrating an example of a memory cell array.

FIG. 3 is a perspective view illustrating representative components of an example of a semiconductor device.

FIG. 4 is a plan layout view of an example of a semiconductor device.

FIG. 5 is an enlarged layout view of a portion A of FIG. 4.

FIG. 6 is a cross-sectional view taken along line B-B′ of FIG. 5.

FIG. 7 is an enlarged view of a portion CX1 of FIG. 6.

FIG. 8 is an example layout view of a common source contact and a back gate contact of FIG. 6.

FIG. 9 is a layout view illustrating an example of a semiconductor device.

FIG. 10 is a cross-sectional view of an example of a semiconductor device.

FIG. 11 is an enlarged view of a portion CX1 of FIG. 10.

FIG. 12 is a cross-sectional view of an example of a semiconductor device.

FIG. 13 is an enlarged view of a portion CX1 of FIG. 12.

FIG. 14 is a cross-sectional view of an example of a semiconductor device.

FIG. 15 is a cross-sectional view of an example of a semiconductor device.

FIGS. 16 to 29 are cross-sectional views illustrating an example of a method of manufacturing a semiconductor device.

FIGS. 30 to 33 are cross-sectional views illustrating an example of a method of manufacturing a semiconductor device.

FIGS. 34 to 36 are cross-sectional views illustrating an example of a method of manufacturing a semiconductor device.

FIG. 37 is a diagram schematically illustrating an example of a data storage system including a semiconductor device.

FIG. 38 is a perspective view schematically illustrating an example of a data storage system including a semiconductor device.

FIG. 39 is a cross-sectional view schematically illustrating an example of a semiconductor package.

### DETAILED DESCRIPTION

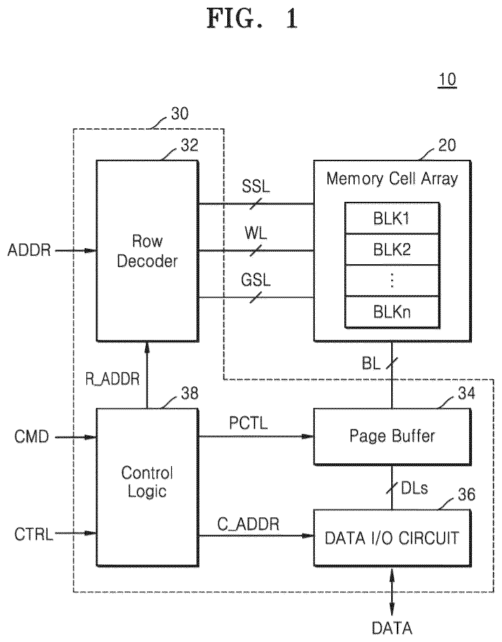

FIG. 1 is a block diagram of an example of a semiconductor device 10.

Referring to FIG. 1, the semiconductor device 10 includes a memory cell array 20 and a peripheral circuit 30. The memory cell array 20 includes a plurality of memory cell blocks BLK1, BLK2, . . . , and BLKn. Each of the plurality of memory cell blocks BLK1, BLK2, . . . , and BLKn may include a plurality of memory cells. The memory cell blocks BLK1, BLK2, . . . , and BLKn may be connected to the peripheral circuit 30 via a bit line BL, a word line WL, a string select line SSL, and a ground select line GSL.

The peripheral circuit 30 may include a row decoder 32, a page buffer 34, a data input/output circuit 36, and a control logic 38. Although not illustrated in FIG. 1, the peripheral circuit 30 may further include an input/output interface, a column logic, a voltage generator, a pre-decoder, a temperature sensor, a command decoder, an address decoder, an amplifier circuit, and the like.

The memory cell array 20 may be connected to the page buffer 34 through the bit line BL and may be connected to the row decoder 32 through the word line WL, the string select line SSL, and the ground select line GSL. In the memory cell array 20, each of a plurality of memory cells included in the plurality of memory cell blocks BLK1, BLK2, . . . , and BLKn may be a flash memory cell. The memory cell array 20 may include a three-dimensional memory cell array. The three-dimensional memory cell array may include a plurality of NAND strings, and each NAND string may include a plurality of memory cells connected to a plurality of word lines WL vertically stacked on a substrate.

The peripheral circuit 30 may receive an address ADDR, a command CMD, and a control signal CTRL from the outside of the semiconductor device 10 and may transmit and receive data DATA to and from a device outside the semiconductor device 10.

The row decoder 32 may select at least one of the plurality of memory cell blocks BLK1, BLK2, . . . , and BLKn in response to the address ADDR from the outside and may select the word line WL, the string select line SSL, and the ground select line GSL of the selected memory cell block. The row decoder 32 may transmit a voltage for performing a memory operation to the word line WL of the selected memory cell block.

The page buffer 34 may be connected to the memory cell array 20 through the bit line BL. The page buffer 34 may operate as a write driver during a program operation to apply, to the bit line BL, a voltage according to the data DATA to be stored in the memory cell array 20 and may operate as a sense amplifier during a read operation to detect the data DATA stored in the memory cell array 20. The page buffer 34 may operate according to a control signal PCTL provided from the control logic 38.

The data input/output circuit 36 may be connected to the page buffer 34 through data lines DLs. The data input/output circuit 36 may receive the data DATA from a memory controller (not shown) during the program operation and may provide program data DATA to the page buffer 34 on the basis of a column address C_ADDR provided from the control logic 38. During the read operation, the data input/output circuit 36 may provide the memory controller with read data DATA stored in the page buffer 34, on the basis of the column address C_ADDR provided from the control logic 38.

The data input/output circuit 36 may transmit, to the control logic 38 or the row decoder 32, an address or command being input. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and provide the column address C_ADDR to the data input/output circuit 36. The control logic 38 may generate various types of internal control signals used within the semiconductor device 10, in response to the control signal CTRL. For example, the control logic 38 may adjust a voltage level provided to the word line WL and the bit line BL when performing a memory operation such as the program operation or an erase operation.

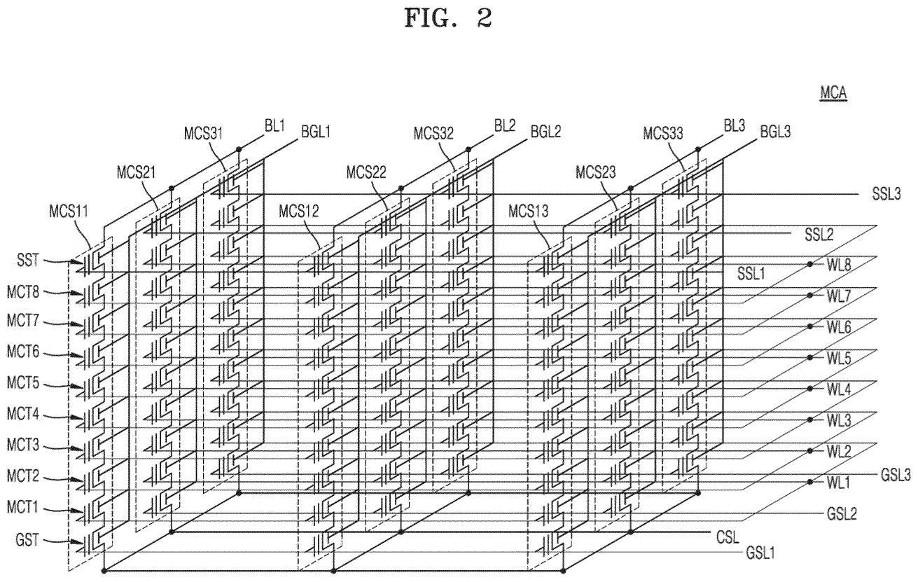

FIG. 2 is a circuit diagram illustrating an example of a memory cell array MCA.

Referring to FIG. 2, a memory cell array MCA may include memory cell strings MCS11 to MCS33, word lines WL1 to WL8, ground select lines GSL1 to GSL3, string select lines SSL1 to SSL3, and a common source line CSL.

The memory cell strings MCS11, MCS21, and MCS31 may be provided among a first bit line BL1, a first back gate line BGL1, and the common source line CSL. The memory cell strings MCS12, MCS22, and MCS32 may be provided among a second bit line BL2, a second back gate line BGL2, and the common source line CSL. The memory cell strings MCS13, MCS23, and MCS33 may be provided among a third bit line BL3, a third back gate line BGL3, and the common source line CSL. Each (e.g., MCS11) of memory cell strings may include a string select transistor SST, a plurality of memory cells MCT1 to MCT8, and a ground select transistor GST, which are connected in series.

The string select transistor SST may be connected to corresponding string select lines SSL1 to SSL3. The plurality of memory cells MCT1 to MCT8 may be respectively connected to corresponding word lines WL1 to WL8. The ground select transistor GST may be connected to the corresponding ground select lines GSL1 to GSL3. The string select transistor SST may be connected to corresponding bit lines BL1 to BL3, and the ground select transistor GST may be connected to the common source line CSL.

In the example of FIG. 2, word lines (e.g., WL1 and the like) of the same height may be commonly connected to each other, the string select lines SSL1 to SSL3 may be separated from one another, and the ground select lines GSL1 to GSL3 may also be separated from one another. Although FIG. 2 illustrates that three string select lines (e.g., SSL1 to SSL3) share a word line that is at the same height, the present disclosure is not limited thereto. For example, two string select lines may share a word line that is at the same height. As another example, four string select lines may share a word line that is at the same height.

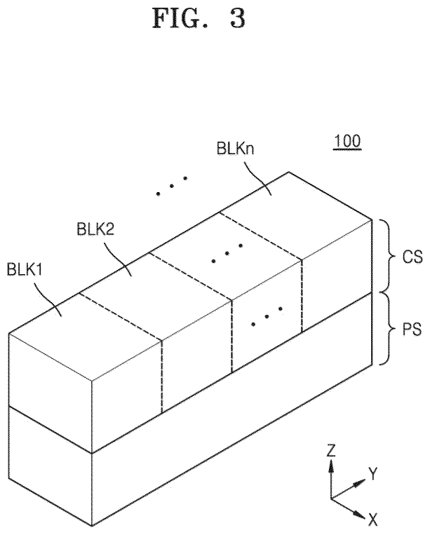

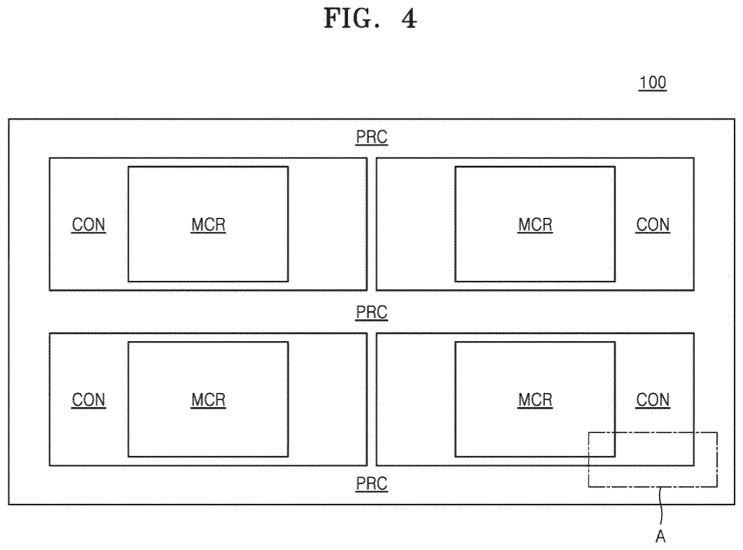

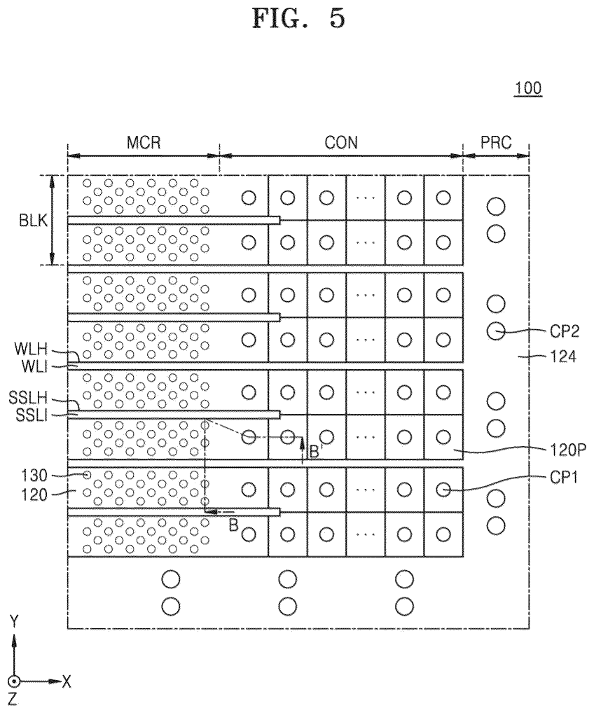

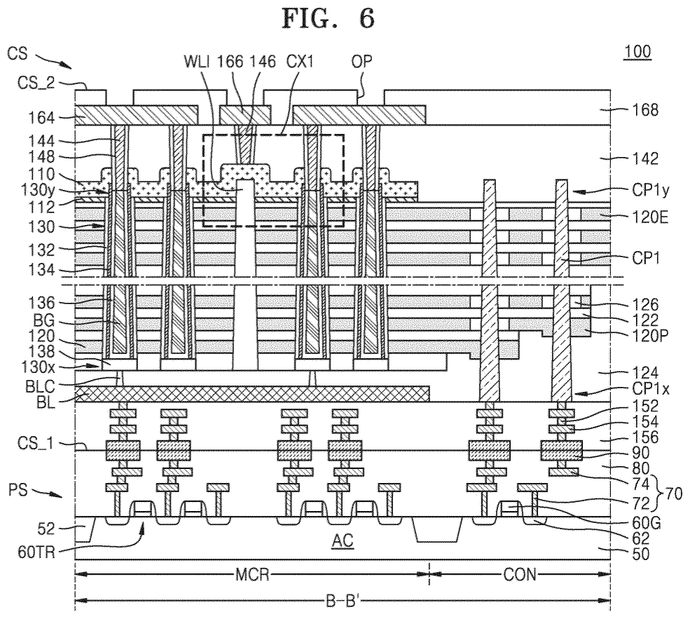

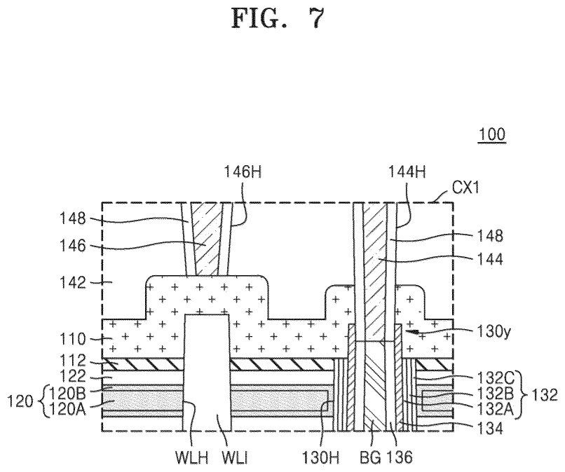

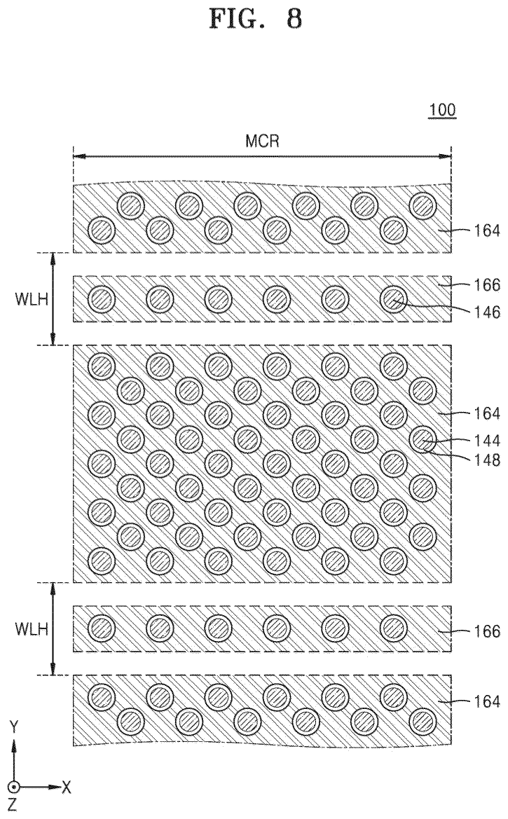

FIG. 3 is a perspective view illustrating representative components of an example of a semiconductor device 100. FIG. 4 is a plan layout view of the semiconductor device 100, and FIG. 5 is an enlarged layout view of a portion A of FIG. 4. FIG. 6 is a cross-sectional view taken along line B-B′ of FIG. 5. FIG. 7 is an enlarged view of a portion CX1 of FIG. 6, and FIG. 8 is an example layout view of a common source contact and a back gate contact of FIG. 6.

Referring to FIGS. 3 to 8, the semiconductor devices 100 may include a cell structure CS and a peripheral circuit structure PS overlapping each other in a vertical direction Z. The cell structure CS may include the memory cell array 20 described with reference to FIG. 1, and the peripheral circuit structure PS may include the peripheral circuit 30 described with reference to FIG. 1.

The cell structure CS may include a plurality of memory cell blocks BLK1, BLK2, . . . , and BLKn. Each of the plurality of memory cell blocks BLK1, BLK2, . . . , and BLKn may include memory cells that are three-dimensionally arranged.

The peripheral circuit structure PS may include a peripheral circuit transistor 60TR and a peripheral circuit wiring structure 70 arranged on a substrate 50. An active region AC may be defined in the substrate 50 by a device isolation layer 52, and a plurality of peripheral circuit transistors 60TR may be formed on the active region AC. Each of the plurality of peripheral circuit transistors 60TR may include a peripheral circuit gate 60G and source/drain regions 62 arranged in portions of the substrate 50 on both sides of the peripheral circuit gate 60G. In the implementations illustrated herein, the phrase “source/drain region” may be understood to mean a source terminal region and/or a drain terminal region of a transistor.

The substrate 50 may include a semiconductor material, for example, a group IV semiconductor, a group III-V compound semiconductor, or a group II-VI oxide semiconductor. For example, the group IV semiconductor may include silicon (Si), germanium (Ge), or silicon-germanium. The substrate 50 may also be provided as a bulk wafer or an epitaxial layer. In an embodiment, the substrate 50 may include a silicon-on-insulator (SOI) substrate or a germanium-on-insulator (GeOI) substrate.

The peripheral circuit wiring structure 70 includes a plurality of peripheral circuit contacts 72 and a plurality of peripheral circuit wiring layers 74. An interlayer insulating layer 80, which covers the peripheral circuit transistor 60TR and the peripheral circuit wiring structure 70, may be arranged on the substrate 50. The plurality of peripheral circuit wiring layers 74 may have a multilayer structure including a plurality of metal layers arranged at different vertical levels. A connection pad 90 may be arranged on the interlayer insulating layer 80, and the peripheral circuit structure PS and the cell structure CS may be electrically connected and bonded to each other by the connection pad 90.

The cell structure CS may include a cell region MCR, a connection region CON, and a peripheral circuit connection region PRC. The cell region MCR may be a region in which a memory cell block BLK including a plurality of memory cell strings extending in the vertical Z direction Z is arranged. A common source layer 110, a plurality of gate electrodes 120, and a channel structure 130, which extends in the vertical direction Z by passing through the gate electrodes 120 and is connected to the common source layer 110, may be arranged in the cell region MCR. An extension portion 120E and a pad portion 120P, which are connected to the plurality of gate electrodes 120, and a first plug CP1, which is electrically connected to the pad portion 120P by passing through the extension portion 120E and the pad portion 120P, may be arranged in the connection region CON. A second plug CP2, which extends in the vertical direction Z and is electrically connected to the peripheral circuit wiring structure 70, may be arranged in the peripheral circuit connection region PCR.

The cell structure CS may include a first surface CS_1 connected to the peripheral circuit structure PS and a second surface CS_2 opposite to the first surface CS_1. FIG. 6 illustrates that the first surface CS_1 of the cell structure CS is arranged on a lower side of the cell structure CS and the second surface CS_2 of the cell structure CS is arranged on an upper side of the cell structure CS. Here, for convenience, as illustrated in the drawings, where a component is arranged close to the first surface CS_1 of the cell structure CS, the component is arranged at a lower vertical level (e.g., the lower side of the cell structure CS), and where a component is arranged close to the second surface CS_2 of the cell structure CS, the component is arranged at a higher vertical level (e.g., the upper side of the cell structure CS).

The gate electrodes 120 may be arranged to be spaced apart from one another in the vertical direction Z in the cell region MCR, and the gate electrodes 120 may be alternately arranged with mold insulating layers 122. The gate electrodes 120 may extend to the connection region CON, and portions of the gate electrodes 120 arranged in the connection region CON may be referred to as the extension portions 120E. The extension portions 120E may have horizontal lengths that gradually increase in a direction toward the second surface CS_2 of the cell structure CS (e.g., in an upward direction in the drawings). The extension portions 120E may have a stepped shape, and the pad portions 120P may be connected to ends of the extension portions 120E. The pad portions 120P may have a greater thickness than the extension portions 120E in the vertical direction Z.

As illustrated in FIG. 7, each of the gate electrodes 120 may include a buried conductive layer 120A and a conductive barrier layer 120B surrounding an upper surface, a bottom surface, and a side surface of the buried conductive layer 120A. For example, the buried conductive layer 120A may include metal such as tungsten, nickel, cobalt, or tantalum, metal silicide such as tungsten silicide, nickel silicide, cobalt silicide, tantalum silicide, doped polysilicon, or a combination thereof. In some implementations, the conductive barrier layer 120B may include titanium nitride, tantalum nitride, tungsten nitride, or a combination thereof.

In some implementations, the gate electrodes 120 may correspond to the ground select lines GSL1 to GSL3, the word lines WL1 to WL8, and at least one string select line SSL1 to SSL3 that constitute the memory cell strings MCS11 to MCS33 of FIG. 2. For example, the uppermost gate electrode 120 may function as the ground select lines GSL1 to GSL3, the lowermost two gate electrodes 120 may function as the string select lines SSL1 to SSL3, and the remaining gate electrodes 120 may function as the word lines WL1 to WL8. Accordingly, the memory cell strings MCS11 to MCS33 in which the ground select transistor GST, the string select transistor SST, and the memory cell transistors MCT1 to MCT8 therebetween are connected in series may be provided. In some implementations, at least one of the gate electrodes 120 may function as a dummy word line, but is not limited thereto.

A stack isolation insulating layer WLI may be arranged within a stack isolation opening WLH that extends in the vertical direction Z by passing through the gate electrodes 120 and the mold insulating layers 122. The stack isolation insulating layer WLI may have an upper surface arranged at a higher vertical level than the uppermost gate electrode 120 and may protrude upwards from the uppermost gate electrode 120. In some implementations, the gate electrodes 120, which are arranged between a pair of stack isolation openings WLH, may constitute one block BLK. In addition, within one block BLK, at least one gate electrode 120 (e.g., the lowermost gate electrode 120) may be separated into two gate electrodes 120 by a string isolation opening SSLH. A string isolation insulating layer SSLI may be arranged within the string isolation opening SSLH.

A stack insulating layer 124 may be arranged to surround the gate electrodes 120, the extension portions 120E, and the pad portions 120P in the connection region CON and the peripheral circuit connection region PCR. From a plan view, the stack insulating layer 124 may be arranged to surround the gate electrodes 120 and may have an upper surface arranged at the same level as the uppermost gate electrode 120 in the peripheral circuit connection region PCR.

A channel structure 130 may be arranged within a channel hole 130H that extends in the vertical direction Z by passing through the gate electrodes 120 and the mold insulating layers 122. The channel structure 130 may include a gate insulating layer 132, a channel layer 134, an insulating liner 136, a drain region 138, and a back gate electrode BG. The gate insulating layer 132, the channel layer 134, the insulating liner 136, and the back gate electrode BG may be sequentially arranged on an inner wall of the channel hole 130H.

The channel structure 130 may include a first end portion 130x arranged adjacent to the peripheral circuit structure PS and a second end portion 130y opposite to the first end portion 130x. In some implementations, the channel structure 130 may have an inclined sidewall such that a width of the first end portion 130x is greater than a width of the second end portion 130y.

The drain region 138, which is electrically connected to the channel layer 134, may be arranged at the first end portion 130x of the channel structure 130. The drain region 138 may be connected to a bit line contact BLC, and the channel layer 134 may be electrically connected to the bit line BL through the drain region 138 and the bit line contact BLC. At the second end portion 130y of the channel structure 130, a portion of a side surface of the channel layer 134 may not be covered by the gate insulating layer 132, and the common source layer 110 may be connected to the portion of the side surface of the channel layer 134. The back gate electrode BG may be connected to a back gate contact 144 at the second end portion 130y of the channel structure 130.

As illustrated in FIG. 7, the gate insulating layer 132 may have a structure sequentially including a tunneling dielectric layer 132A, a charge storage layer 132B, and a blocking dielectric layer 132C on an outer wall of the channel layer 134. Relative thicknesses of the tunneling dielectric layer 132A, the charge storage layer 132B, and the blocking dielectric layer 132C forming the gate insulating layer 132 are not limited to those illustrated in FIG. 7 and may be variously modified.

The tunneling dielectric layer 132A may include silicon oxide, hafnium oxide, aluminum oxide, zirconium oxide, tantalum oxide, or the like.

The charge storage layer 132B may be a region in which electrons passing through the tunneling dielectric layer 132A from the channel layer 134 are stored and may include silicon nitride, boron nitride, silicon boron nitride, or polysilicon doped with impurities. The blocking dielectric layer 132C may include silicon oxide, silicon nitride, or metal oxide having a higher dielectric constant than silicon oxide. The metal oxide may include hafnium oxide, aluminum oxide, zirconium oxide, tantalum oxide, or a combination thereof.

In some implementations, the charge storage layer 132B may include a ferroelectric dielectric material. In this case, the charge storage layer 132B may include a metal oxide having ferroelectric material characteristics. For example, the charge storage layer 132B may include a ferroelectric material capable of storing data through a hysteresis behavior due to a voltage applied to the charge storage layer 132B. In some implementations, the charge storage layer 132B may include at least one of hafnium oxide, zirconium oxide, and hafnium zirconium oxide.

The back gate electrode BG may extend in the vertical direction Z within the channel hole 130H. The back gate electrode BG may have a vertical pillar shape, and the insulating liner 136 may be arranged on a sidewall of the back gate electrode BG. The back gate electrode BG may be electrically insulated from the channel layer 134 by the insulating liner 136 located therebetween. At the first end portion 130x of the channel structure 130, a bottom surface of the back gate electrode BG may be covered by the insulating liner 136, and the insulating liner 136 may be located between the bottom surface of the back gate electrode BG and the drain region 138. At the second end portion 130y of the channel structure 130, an upper surface of the back gate electrode BG may not be covered by the insulating liner 136, and the back gate contact 144 may be arranged on the upper surface of the back gate electrode BG.

In some implementations, the back gate electrode BG may include a doped polysilicon layer, but the material choice is not limited thereto. When a data write operation, a read operation, or an erase operation is performed on the memory cells MCT1 to MCT8 of FIG. 1, a certain voltage (or signal) may be applied to the back gate electrode BG from the back gate lines BGL1 to BGL3 of FIG. 1.

An etch stop layer 112 may be arranged on the uppermost gate electrode 120, and the etch stop layer 112 may include polysilicon. In some implementations, the etch stop layer 112 may be omitted.

The common source layer 110 may be conformally formed on the etch stop layer 112 to be connected to the second end portion 130y of the channel structure 130 and cover an upper surface of the stack isolation insulating layer WLI. From a plan view, the common source layer 110 may be arranged over the entire region of the cell region MCR. A portion of the common source layer 110 in contact with the etch stop layer 112 may have an upper surface arranged at a different vertical level from a portion of the common source layer 110 in contact with the second end portion 130y of the channel structure 130. In addition, in some implementations, a portion of the common source layer 110 in contact with the stack isolation insulating layer WLI may have an upper surface arranged at a different vertical level from a portion of the common source layer 110 in contact with the second end portion 130y of the channel structure 130.

In some implementations, as illustrated in FIG. 7, the common source layer 110 may conformally cover an upper surface of the channel layer 134 and an upper surface of the gate insulating layer 132. For example, the gate insulating layer 132 may be arranged at a lower level than the upper surface of the channel layer 134, and accordingly, portions of the upper surface and a sidewall of the channel layer 134 may be covered by the common source layer 110 to ensure a sufficient contact area between the channel layer 134 and the common source layer 110. In some implementations, as illustrated in FIG. 7, an upper surface of the charge storage layer 132B may be arranged at the same level as upper surfaces of the tunneling dielectric layer 132A and the blocking dielectric layer 132C, and thus, the gate insulating layer 132 may have a flat horizontal level. In some implementations, the charge storage layer 132B may be arranged such that the upper surface thereof protrudes more upwards than the upper surfaces of the tunneling dielectric layer 132A and the blocking dielectric layer 132C.

In some implementations, a first end portion CP1x of the first plug CP1 may be arranged at a location adjacent to the peripheral circuit structure PS, and a second portion CP1y of the first plug CP1 may be arranged opposite to the first end portion CP1x. The first plug CP1 may have an inclined sidewall such that a width of the first end portion CP1x is greater than a width of the second end portion CP1y.

In some implementations, the first plug CP1 may include a metal such as tungsten, nickel, cobalt, or tantalum, a metal nitride such as titanium nitride, tantalum nitride, or tungsten nitride, a metal silicide such as tungsten silicide, nickel silicide, cobalt silicide, or tantalum silicide, doped polysilicon, or a combination thereof.

In the peripheral circuit connection region PRC, the second plug CP2 may be arranged to pass through the stack insulating layer 124. A shape and constituent material of the second plug CP2 may be similar to a shape and constituent material of the first plug CP1.

A connection via 152, a connection wiring layer 154, and an interlayer insulating layer 156 surrounding the connection via 152 and the connection wiring layer 154 may be arranged between the stack insulating layer 124 and the peripheral circuit structure PS. The connection via 152 and the connection wiring layer 154 may be constituted in multiple layers to be arranged at a plurality of vertical levels, and the bit line BL, the first plug CP1, and the second plug CP2 may be electrically connected to the peripheral circuit structure PS through the connection pad 90.

An upper insulating layer 142 may be arranged on the common source layer 110. The upper insulating layer 142 may have a flat upper surface throughout the cell region MCR and the connection region CON. The upper insulating layer 142 may be disposed to cover the upper surface of the common source layer 110 and an upper surface of the first plug CP1.

The back gate contact 144 may be arranged within a first backside contact hole 144H passing through the upper insulating layer 142 and the common source layer 110. The back gate contact 144 may be arranged at a location vertically overlapping each channel structure 130. For example, as illustrated in FIG. 8, the back gate contact 144 may be arranged to be offset in a first horizontal direction X and a second horizontal direction Y. A spacer 148 may be arranged on an inner wall of the first backside contact hole 144H, and the spacer 148 may surround a sidewall of the back gate contact 144. The sidewall of the back gate contact 144 may be surrounded by the spacer 148, and thus, the back gate contact 144 may be electrically isolated from the common source layer 110.

As illustrated in FIG. 7, a bottom portion of the first backside contact hole 144H may extend into the second end portion 130y of the channel structure 130, and the bottom portion of the first backside contact hole 144H may be surrounded by an end portion of the channel layer 134. For example, at the bottom portion of the first backside contact hole 144H, a bottom surface of the back gate contact 144 may contact the upper surface of the back gate electrode BG, and a bottom portion of the back gate contact 144 may be surrounded by the channel layer 134 with the spacer 148 therebetween. An upper surface of the back gate contact 144 may be arranged at the same vertical level as an upper surface of the upper insulating layer 142.

A common source contact 146 may be arranged within a second backside contact hole 146H passing through the upper insulating layer 142. The second backside contact hole 146H may pass through the upper insulating layer 142 but may not pass through the common source layer 110, and the upper surface of the common source layer 110 may be arranged at a bottom portion of the second backside contact hole 146H. The second backside contact hole 146H may be arranged to be spaced apart from the first backside contact hole 144H in a horizontal direction, e.g., the common source contact 146 may be arranged at a location vertically overlapping the stack isolation opening WLH or the stack isolation insulating layer WLI. For example, as illustrated in FIG. 8, the common source contacts 146 may be arranged in a row in the first horizontal direction X.

The spacer 148 may be arranged on an inner wall of the second backside contact hole 146H, and the spacer 148 may surround a sidewall of the common source contact 146. In some implementations, an upper surface of the common source contact 146 may be arranged at the same vertical level as an upper surface of the upper insulating layer 142.

In some implementations, a portion of the spacer 148 arranged on the inner wall of the second backside contact hole 146H may be formed in the same process as a portion of the spacer 148 arranged on the inner wall of the first backside contact hole 144H, and the common source contact 146 arranged inside the second backside contact hole 146H may be formed in the same process as the back gate contact 144 arranged inside the first backside contact hole 144H.

In some implementations, the back gate contact 144 and the common source contact 146 may include a metal, e.g., tungsten, nickel, cobalt, or tantalum, a metal nitride, e.g., titanium nitride, tantalum nitride, or tungsten nitride, a metal silicide, e.g., tungsten silicide, nickel silicide, cobalt silicide, or tantalum silicide, or a combination thereof. In some implementations, the spacer 148 may include at least one of silicon nitride, silicon oxide, and silicon oxynitride.

A first backside wiring layer 164 and a second backside wiring layer 166 may be arranged on the upper insulating layer 142. The first backside wiring layer 164 may be electrically connected to the back gate contact 144, and the second backside wiring layer 166 may be arranged to be spaced apart from the first backside wiring layer 164 in the horizontal direction and may be electrically connected to the common source contact 146. For example, as illustrated in FIG. 8, the second backside wiring layer 166 may be located at a location vertically overlapping the stack isolation opening WLH and may be electrically connected to the common source layer 110 through the common source contact 146. The first backside wiring layer 164 may be arranged in a region between two adjacent stack isolation openings WLH, e.g., at location vertically overlapping the channel structure 130. The first backside wiring layer 164 may be commonly and electrically connected to the back gate electrodes BG of a plurality of channel structures 130 arranged between two adjacent stack isolation openings WLH (or between two adjacent stack isolation insulating layers WLI).

A passivation layer 168 may be arranged on the first backside wiring layer 164 and the second backside wiring layer 166, and an opening OP of the passivation layer 168 may be arranged to expose at least one of a portion of an upper surface of the first backside wiring layer 164 and a portion of an upper surface of the second backside wiring layer 166. The first backside wiring layer 164 may be configured to apply a back gate voltage from an external connection terminal to the back gate electrode BG within the channel structure 130 through the back gate contact 144, and/or the first backside wiring layer 164 may be electrically connected to the peripheral circuit structure PS through the second plug CP2 of FIG. 4. The second backside wiring layer 166 may be configured to apply a common source voltage to the common source layer 110 from the external connection terminal through the common source contact 146, and/or the second backside wiring layer 166 may be electrically connected to the peripheral circuit structure PS through the second plug CP2 of FIG. 4.

In some implementations, the back gate electrode BG may be included within the channel structure 130. For example, when the back gate electrode BG is included within the channel structure 130, for a programming operation, a back gate voltage may be applied to the back gate electrode BG, a programming voltage may be applied to a selected word line, and a relatively low pass voltage (e.g., 0 V) may be applied to an unselected word line. Therefore, in the disclosed semiconductor device, when a relatively high pass voltage is applied to an unselected word line, disturbances in data storage in an unselected memory cell may be prevented or minimized.

In addition, the back gate contact 144 and the first backside wiring layer 164 for providing an electrical connection to the back gate electrode BG may be provided on the second surface CS_2 of the cell structure CS, and thus, areas and degrees of freedom of the arrangement of the back gate contact 144 and the first backside wiring layer 164 may be improved. In addition, the back gate contact 144 and the first backside wiring layer 164 may be simultaneously formed in a manufacturing process for forming the common source contact 146 and the second backside wiring layer 166, respectively, and accordingly, a process of forming the back gate contact 144 and the first backside wiring layer 164 may not be added.

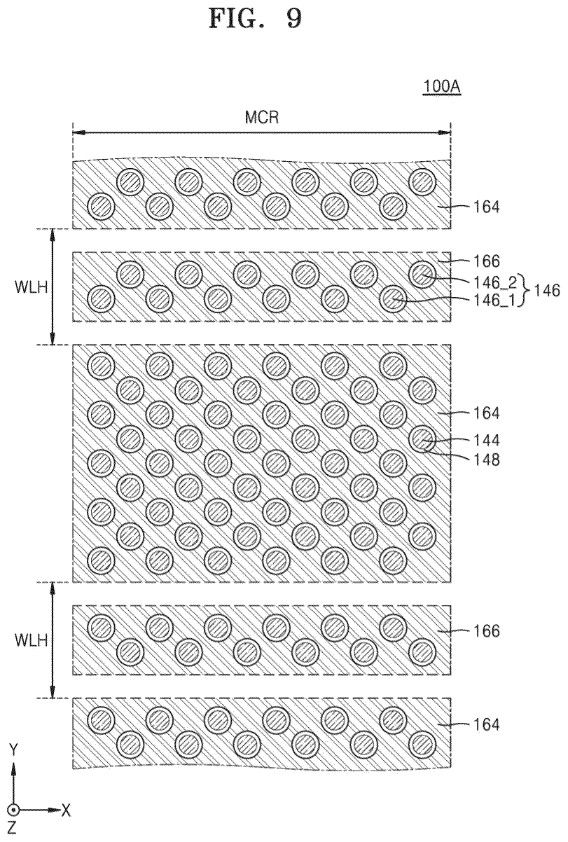

FIG. 9 is a layout view illustrating an example of a semiconductor device 100A.

Referring to FIG. 9, a second backside wiring layer 166 may be arranged at a location vertically overlapping a stack isolation opening WLH, and the second backside wiring layer 166 may have a line-type planar shape extending in a first horizontal direction X. A first backside wiring layer 164 may be arranged in a region between two adjacent stack isolation openings WLH, e.g., at a location vertically overlapping the channel structure 130 of FIG. 6. A common source contact 146 may include first sets 146_1 arranged in a row in the first horizontal direction X at a location vertically overlapping the second backside wiring layer 166, and second sets 146_2 spaced apart from the first sets 146_1 in a second horizontal direction Y and arranged in a row in the first horizontal direction X.

In some implementations, at a location vertically overlapping one second backside wiring layer 166, the common source contact 146 may further include additional sets spaced apart from the first sets 146_1 and the second sets 146_2 in the second horizontal direction Y and arranged in a row in the first horizontal direction X.

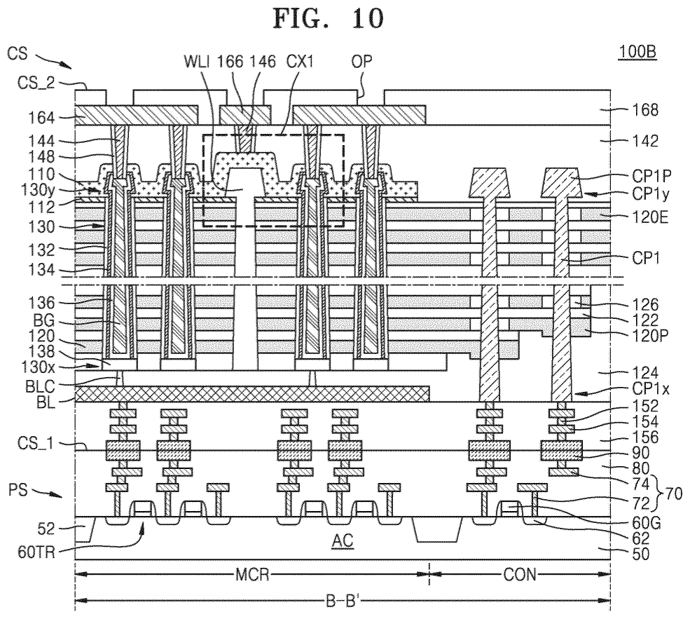

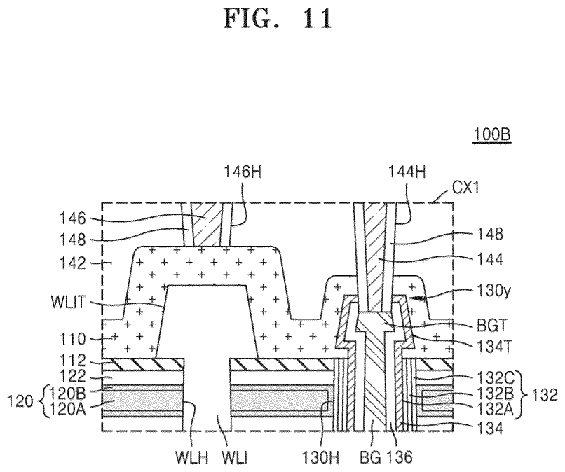

FIG. 10 is a cross-sectional view of an example of a semiconductor device 100B. FIG. 11 is an enlarged view of a portion CX1 of FIG. 10.

Referring to FIGS. 10 and 11, a portion of a channel layer 134 has a shape extending in a horizontal direction at a second end portion 130y of a channel structure 130. For example, an extension portion 134T of the channel layer 134, which is arranged at a higher vertical level than an etch stop layer 112, may have a greater width than a portion of the channel layer 134 arranged at a lower vertical level than the etch stop layer 112 (e.g., a portion of the channel layer 134 arranged at the same vertical level as a gate electrode 120 and surrounded by the gate electrode 120). An insulating liner 136 may be formed to have a conformal thickness within the extension portion 134T of the channel layer 134.

A portion of a back gate electrode BG may have a shape extending in the horizontal direction at the second end portion 130y of the channel structure 130. For example, an extension portion BGT of the back gate electrode BG, which is arranged at a higher vertical level than the etch stop layer 112, may have a greater width than a portion of the back gate electrode BG arranged at a lower vertical level than the etch stop layer 112.

A back gate contact 144 may be arranged on an upper surface of the extension portion BGT of the back gate electrode BG, and accordingly, the back gate contact 144 may be formed to have a relatively great width, and/or a relatively great contact area between the back gate contact 144 and the upper surface of the extension portion BGT of the back gate electrode BG may be secured.

A portion of a stack isolation insulating layer WLI, which is arranged at a higher vertical level than the etch stop layer 112, may have a shape extending in the horizontal direction. For example, an extension portion WLIT of the stack isolation insulating layer WLI, which is arranged at a higher vertical level than the etch stop layer 112, may have a greater width than a portion of the stack isolation insulating layer WLI arranged at a lower vertical level than the etch stop layer 112.

A second end portion CP1y of a first plug CP1 may further include a landing pad portion CP1P. The landing pad portion CP1P may have a shape extending in the horizontal direction to have a greater width than a portion of the first plug CP1 surrounded by the gate electrode 120.

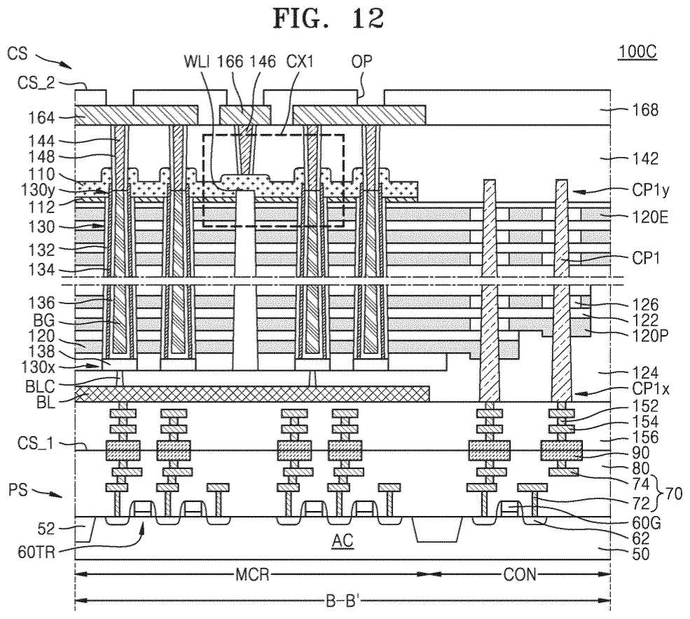

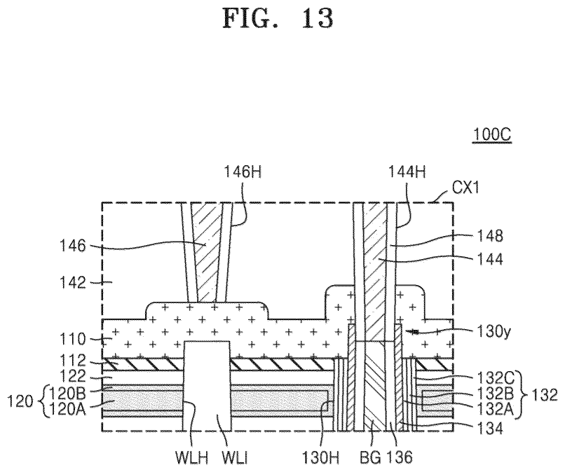

FIG. 12 is a cross-sectional view of an example of a semiconductor device 100C. FIG. 13 is an enlarged view of a portion CX1 of FIG. 12.

Referring to FIGS. 12 and 13, a stack isolation insulating layer WLI has an upper surface arranged at a lower level than a second end portion 130y of a channel structure 130. For example, the upper surface of the stack isolation insulating layer WLI may be arranged at a higher vertical level than an etch stop layer 112 and may be arranged at a lower vertical level than an upper surface of a channel layer 134 of the channel structure 130 or an upper surface of a back gate electrode BG.

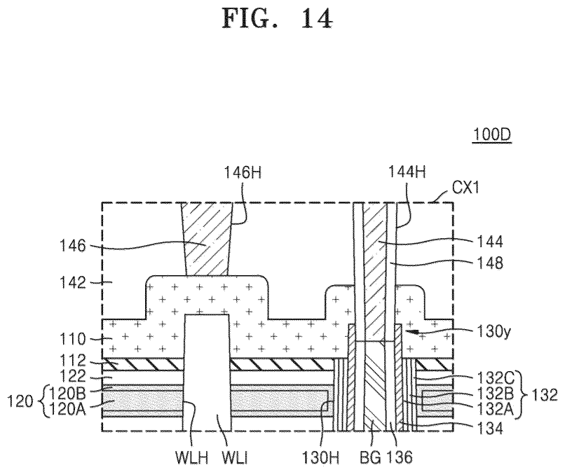

FIG. 14 is a cross-sectional view of an example of a semiconductor device 100D.

Referring to FIG. 14, a spacer 148 is arranged on an inner wall of a first backside contact hole 144H, but the spacer 148 may not be arranged on an inner wall of a second backside contact hole 146H. A common source contact 146 may be arranged on the inner wall of the second backside contact hole 146H, and a sidewall of the common source contact 146 may be surrounded by an upper insulating layer 142 and may contact the upper insulating layer 142.

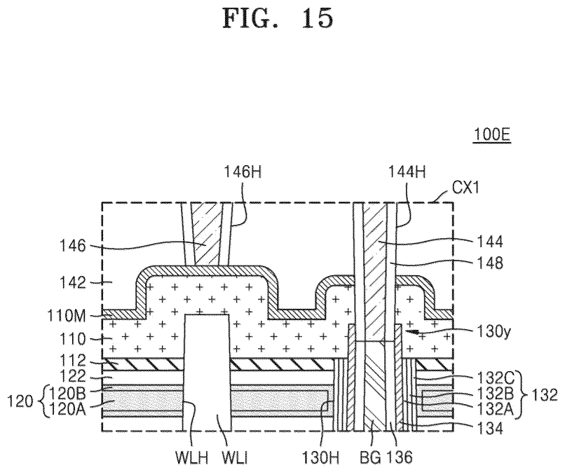

FIG. 15 is a cross-sectional view of an example of a semiconductor device 100E.

Referring to FIG. 15, an upper conductive layer 110M may be further arranged on an upper surface of a common source layer 110. The upper conductive layer 110M may include a metal nitride such as titanium nitride, tantalum nitride, or tungsten nitride, a metal such as tungsten, molybdenum, chromium, nickel, cobalt, or tantalum, a metal silicide such as tungsten silicide, nickel silicide, cobalt silicide, or tantalum silicide, or a combination thereof. In some implementations, the upper conductive layer 110M may be formed in a stacked structure of two or more different material layers.

A first backside contact hole 144H may extend in a vertical direction by passing through the upper insulating layer 142, the upper conductive layer 110M, and the common source layer 110, a spacer 148 may be arranged on an inner wall of the first backside contact hole 144H, and a back gate contact 144 may be arranged inside the first backside contact hole 144H. The back gate contact 144 may be electrically isolated from the upper conductive layer 110M and the common source layer 110 by the spacer 148.

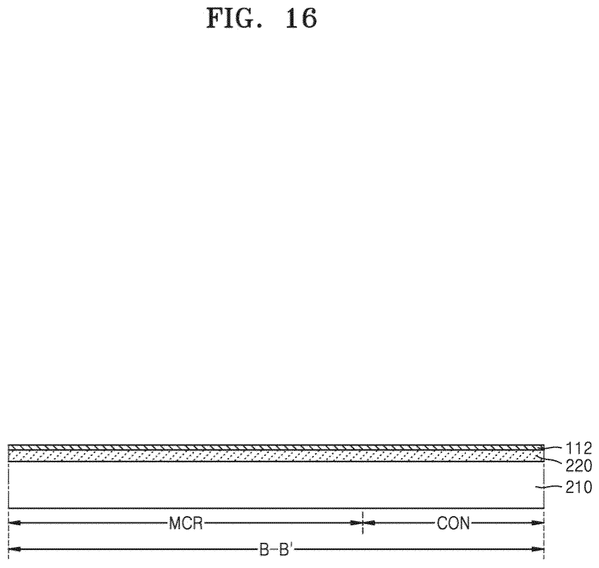

FIGS. 16 to 29 are cross-sectional views illustrating an example of a method of manufacturing a semiconductor device 100.

Referring to FIG. 16, a buffer insulating layer 220 is formed on a cell substrate 210, and an etch stop layer 112 may be formed on the buffer insulating layer 220.

In some implementations, the cell substrate 210 may include at least one of silicon (Si), germanium (Ge), silicon germanium (SiGe), gallium arsenide (GaAs), indium gallium arsenide (InGaAs), aluminum gallium arsenide (AlGaAs), or a mixture thereof. The buffer insulating layer 220 may be formed by using silicon oxide. In some implementations, the etch stop layer 112 may be formed by using polysilicon.

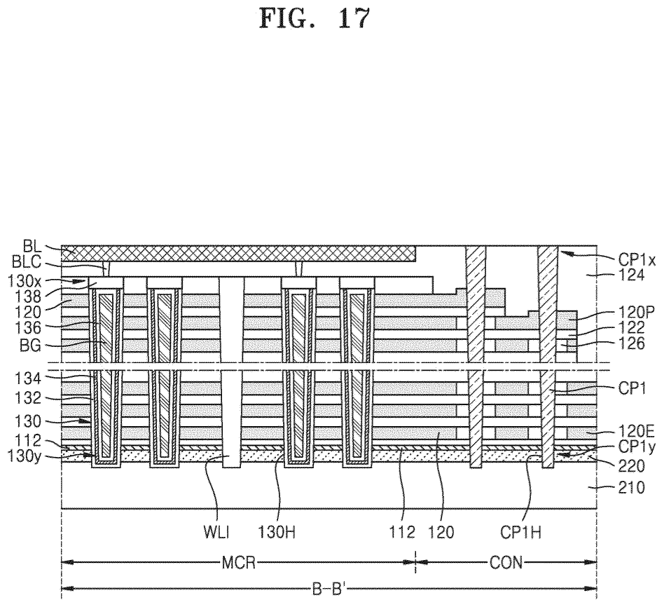

Referring to FIG. 17, gate electrodes 120 and mold insulating layers 122 are alternately formed in a cell region MCR and a connection region CON, and extension portions 120E and a pad portion 120P, which are connected to the gate electrodes 120, may be formed in the connection region CON. In addition, a channel structure 130, which extends in a vertical direction Z by passing through the gate electrodes 120, and a bit line BL, which is connected to the channel structure 130, may be formed in the cell region MCR. In addition, a first plug CP1, which passes through the extension portions 120E and the pad portion 120P, may be formed in the connection region CON, and the second plug CP2 of FIG. 5, which passes through a stack insulating layer 124, may be formed in the peripheral circuit connection region PRC of FIG. 4.

In some implementations, in a process of forming the gate electrode 120 and the pad portion 120P, a mold stack, which alternately includes sacrificial layers (not shown) and the mold insulating layers 122 on the etch stop layer 112, may be formed in the cell region MCR and the connection region CON. Portions of the mold stack may be patterned in the connection region CON to form a preliminary pad portion (not shown), and then the sacrificial layers and the preliminary pad portion may be removed. The gate electrode 120 and the pad portion 120P may be formed in a space from which the sacrificial layers and the preliminary pad portion are removed.

In some implementations, in a process for forming the channel structure 130, a channel hole 130H, which passes through the mold stack, may be formed in the cell region MCR, a gate insulating layer 132, a channel layer 134, an insulating liner 136, and a back gate electrode BG may be sequentially formed on an inner wall of the channel hole 130H, and a drain region 138 may be formed at an entrance of the channel hole 130H.

In some implementations, the back gate electrode BG may be surrounded by the insulating liner 136 to be electrically insulated from the channel layer 134 and the drain region 138. In some implementations, a portion of the insulating liner 136, which covers the channel layer 134, may be first formed on a sidewall and a bottom portion of the channel hole 130H, and then the back gate electrode BG, which fills the remaining portion of the channel hole 130H, may be formed on the portion of the insulating liner 136, a portion of the back gate electrode BG, which is arranged at the entrance of the channel hole 130H, may be removed, and another portion of the insulating liner 136 may be formed on an upper surface of the back gate electrode BG. Subsequently, the drain region 138, which fills the entrance of the channel hole 130H, may be formed on the other portion of the insulating liner 136.

A first end portion 130x of the channel structure 130 may be arranged at a higher vertical level than a second end portion 130y, and the second end portion 130y may be formed to pass through the etch stop layer 112 and extend into a cell substrate 210.

In some implementations, in the process of forming the first plug CP1, a first end portion CP1x of the first plug CP1 may be formed to have a greater width than a second end portion CP1y, and the second end portion CP1y of the first plug CP1 may be formed to have a great height to pass through the etch stop layer 112 and extend into the cell substrate 210. In some implementations, a first plug hole CP1H, which passes through the mold stack, may be formed in the connection region CON, a portion of the sacrificial layer, which is exposed on a sidewall of the first plug hole CP1H, may be removed by lateral etching, and an insulating pattern 126 may be formed in a portion from which the sacrificial layer is removed. Subsequently, the first plug CP1 may be formed within the first plug hole CP1H.

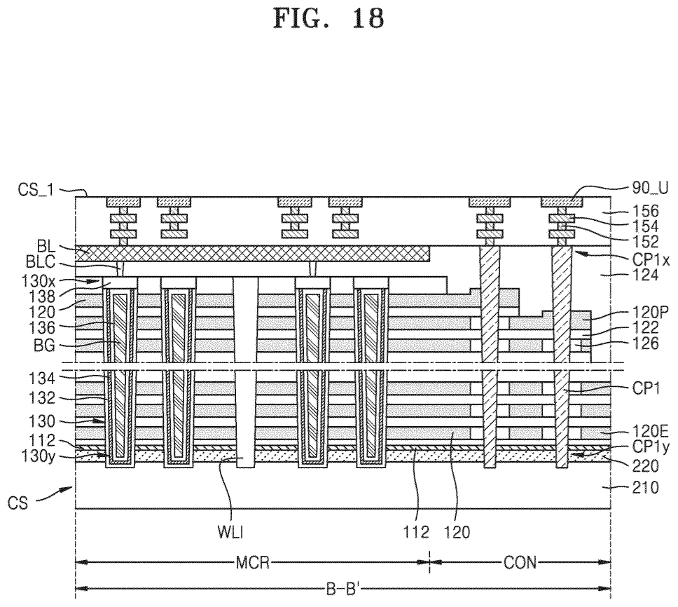

Referring to FIG. 18, a connection via 152, a connection wiring layer 154, and an interlayer insulating layer 156, which are electrically connected to the bit line BL and the first plug CP1, are formed. A connection pad 90_U may be formed on an upper surface of the interlayer insulating layer 156.

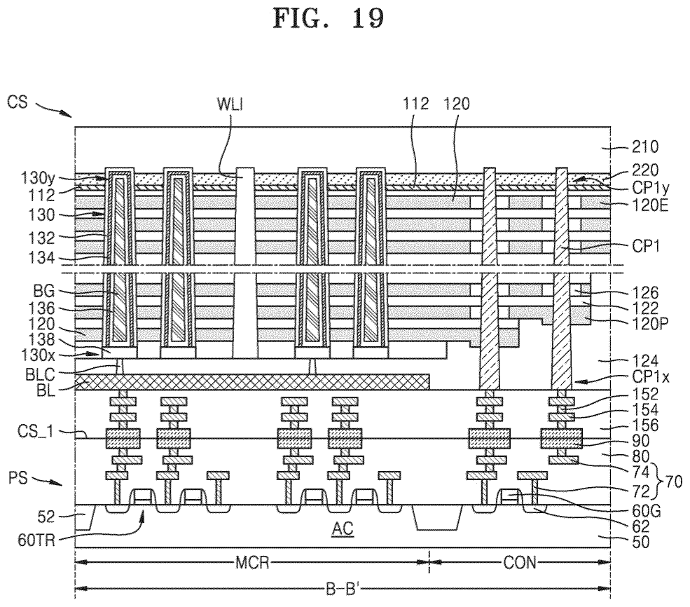

Referring to FIG. 19, a peripheral circuit structure PS is provided. The peripheral circuit structure PS may include a peripheral circuit transistor 60TR and a peripheral circuit wiring structure 70 which are arranged on a substrate 50. An active region AC may be defined in the substrate 50 by a device isolation layer 52, and a plurality of peripheral circuit transistors 60TR may be formed on the active region AC. Each of the plurality of peripheral circuit transistors 60TR may include a peripheral circuit gate 60G and source/drain regions 62 arranged in portions of the substrate 50 on both sides of the peripheral circuit gate 60G.

Subsequently, the peripheral circuit structure PS may be attached to a cell structure CS. The peripheral circuit structure PS and the cell structure CS may be attached to each other through a connection pad 90 and interlayer insulating layers 80 and 154 in a metal-oxide hybrid bonding method, but methods of attaching the peripheral circuit structure PS and the cell structure CS are not limited thereto.

Subsequently, a structure in which the peripheral circuit structure PS and the cell structure CS are attached to each other may be turned over so that the cell substrate 210 faces upwards.

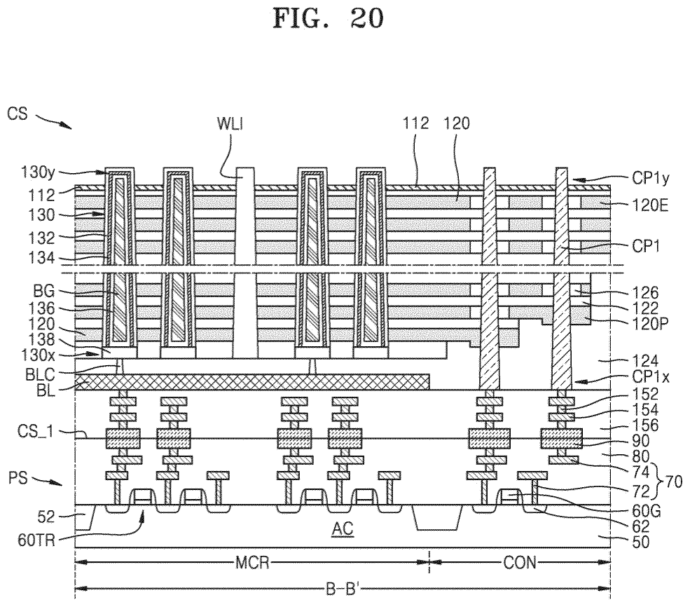

Referring to FIG. 20, the cell substrate 210 of FIG. 18 may be removed. The cell substrate 210 may be removed by a grinding process and a subsequent etching process, and the buffer insulating layer 220 of FIG. 18 may be exposed.

Subsequently, the buffer insulating layer 220 may also be removed and an upper surface of the etch stop layer 112 may be exposed. The buffer insulating layer 220 may be removed, and thus, the second end portion 130y of the channel structure 130 and the second end portion CP1y of the first plug CP1 may protrude from the upper surface of the etch stop layer 112.

The cell substrate 210 and the buffer insulating layer 220 may be removed, and thus, an upper side of a stack isolation insulating layer WLI may also be exposed and protrude above the etch stop layer 112.

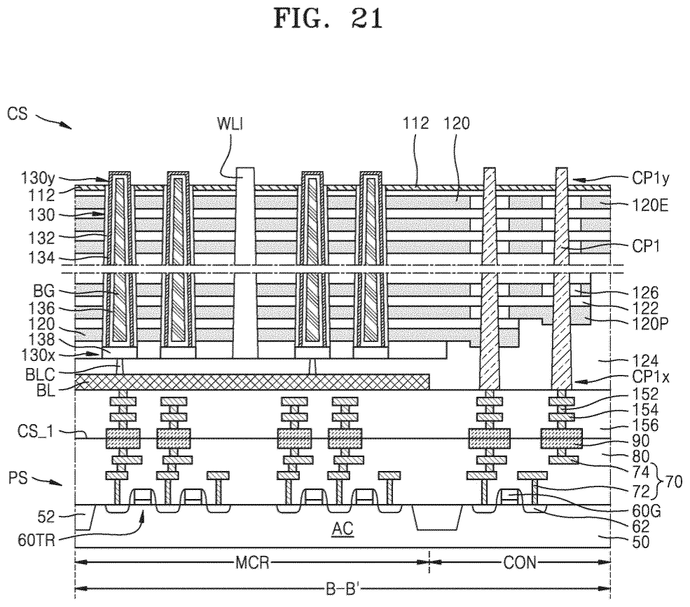

Referring to FIG. 21, a portion of the gate insulating layer 132, which is exposed at the second end portion 130y of the channel structure 130, may be removed to expose an upper surface of the channel layer 134. The process of removing the gate insulating layer 132 may be performed so that the upper surface of the etch stop layer 112 is exposed in the process of removing the gate insulating layer 132. In some implementations, an upper side of the gate insulating layer 132 may be removed such that the gate insulating layer 132 is arranged at a lower level than the upper surface of the channel layer 134 and portions of the upper surface and a sidewall of the channel layer 134 are exposed.

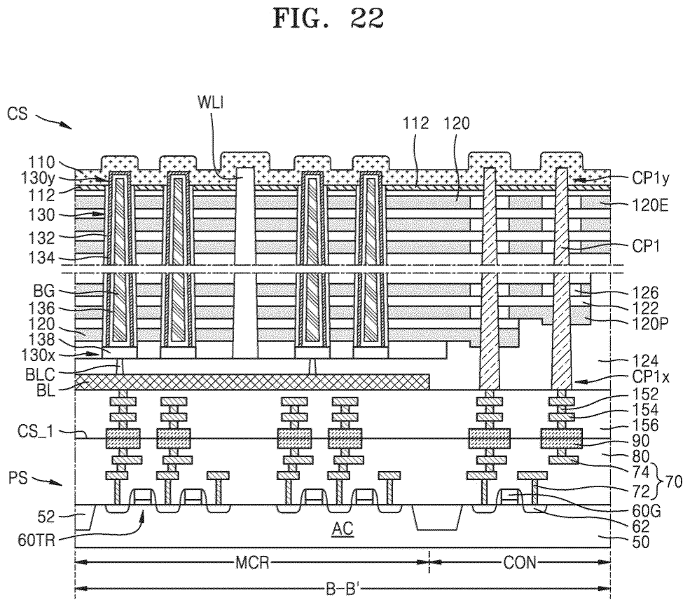

Referring to FIG. 22, a common source layer 110 may be formed on the cell region MCR, the connection region CON, and the peripheral circuit connection region PRC. The common source layer 110 may be formed by using polysilicon. For example, the common source layer 110 may be formed by using polysilicon doped with n-type impurities. In the cell region MCR, the common source layer 110 may be conformally formed on the exposed upper surfaces of the etch stop layer 112 and the channel layer 134. In the connection region CON, the common source layer 110 may cover the second end portion CP1y of the first plug CP1.

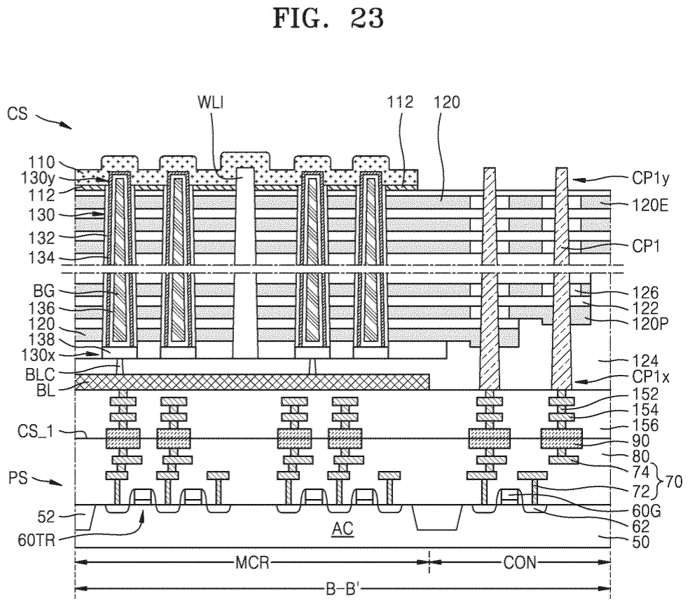

Referring to FIG. 23, a portion of the common source layer 110 and a portion of the etch stop layer 112, which are arranged in the connection region CON and the peripheral circuit connection region PRC, may be removed.

In some implementations, a mask pattern may be formed on the common source layer 110 in the cell region MCR, and portions of the common source layer 110 and the etch stop layer 112, which are arranged in the connection region CON and the peripheral circuit connection region PRC, may be removed by using the mask pattern as an etching mask. The common source layer 110 and the etch stop layer 112, which are arranged in the connection region CON and the peripheral circuit connection region PRC, may be removed, and thus, the second end portion CP1y of the first plug CP1 and the uppermost mold insulating layer 122 may be exposed again.

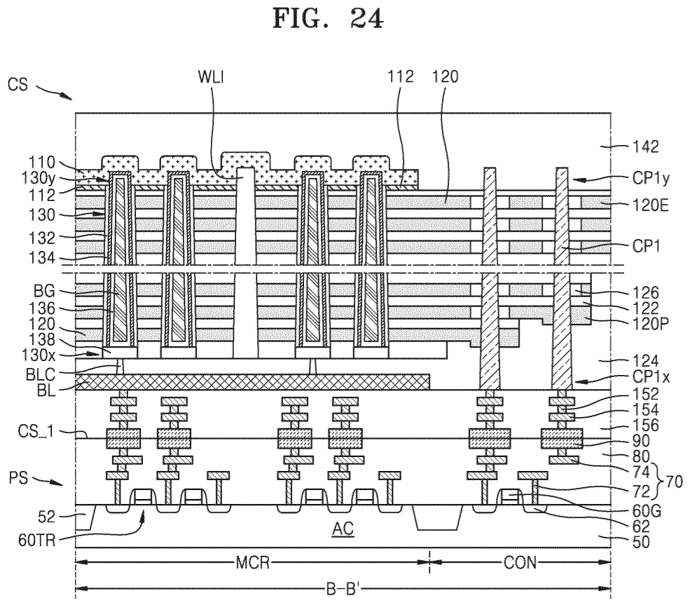

Referring to FIG. 24, an upper insulating layer 142 may be formed on the common source layer 110 and the uppermost mold insulating layer 122 in the cell region MCR, the connection region CON, and the peripheral circuit connection region PRC. The upper insulating layer 142 may be formed to have a sufficiently great height to cover both the common source layer 110 and the second end portion CP1y of the first plug CP1 and have a flat upper surface level.

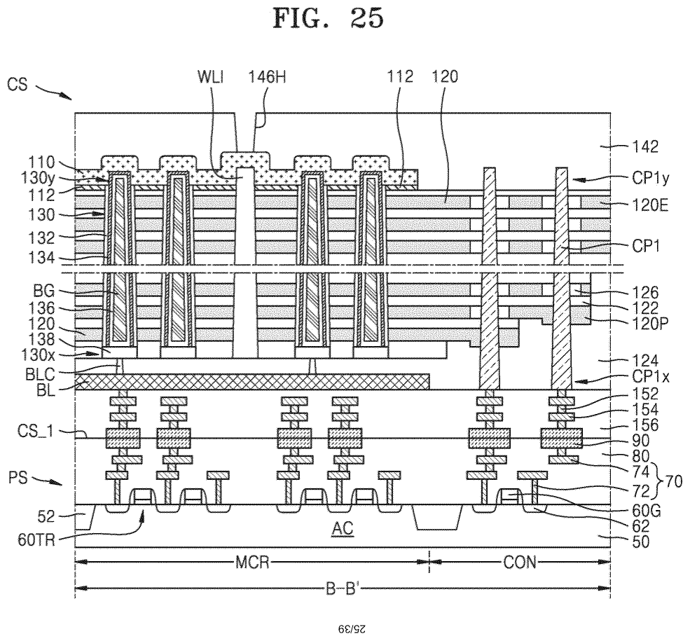

Referring to FIG. 25, a mask pattern may be formed on the upper insulating layer 142 and a second backside contact hole 146H may be formed by removing a portion of the upper insulating layer 142 by using the mask pattern as an etching mask.

In some implementations, the second backside contact hole 146H may be formed at a location vertically overlapping the stack isolation insulating layer WLI. The upper surface of the common source layer 110 may be arranged on a bottom portion of the second backside contact hole 146H.

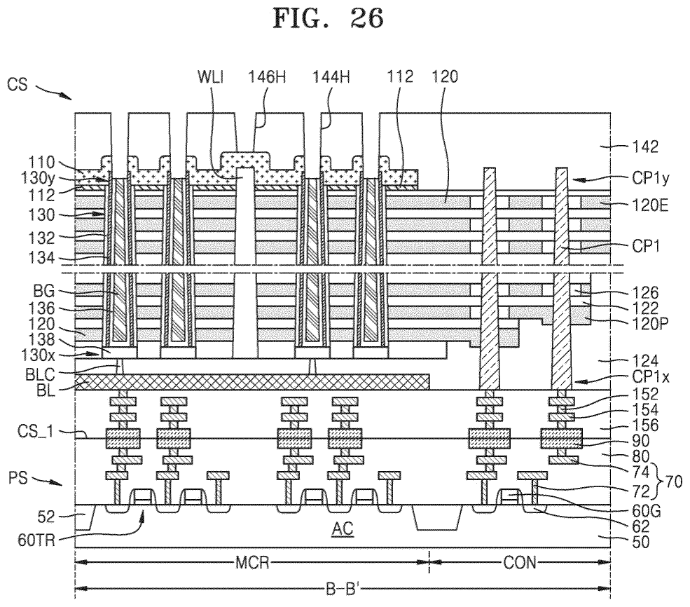

Referring to FIG. 26, a mask pattern may be formed on the upper insulating layer 142 and a first backside contact hole 144H may be formed by removing a portion of the upper insulating layer 142 and a portion of the common source layer 110 by using the mask pattern as an etching mask.

In some implementations, the first backside contact hole 144H may be formed at a location vertically overlapping the channel structure 130. In the process of forming the first backside contact hole 144H, a horizontal extension portion of the channel layer 134, which is arranged at the second end portion 130y of the channel structure 130, may be removed, and then a horizontal extension portion of the insulating liner 136, which is arranged underneath the horizontal extension portion of the channel layer 134, may be removed. After the horizontal extension portion of the channel layer 134 and the horizontal extension portion of the insulating liner 136 are removed, an upper surface of the back gate electrode BG may be exposed on a bottom portion of the first backside contact hole 144H.

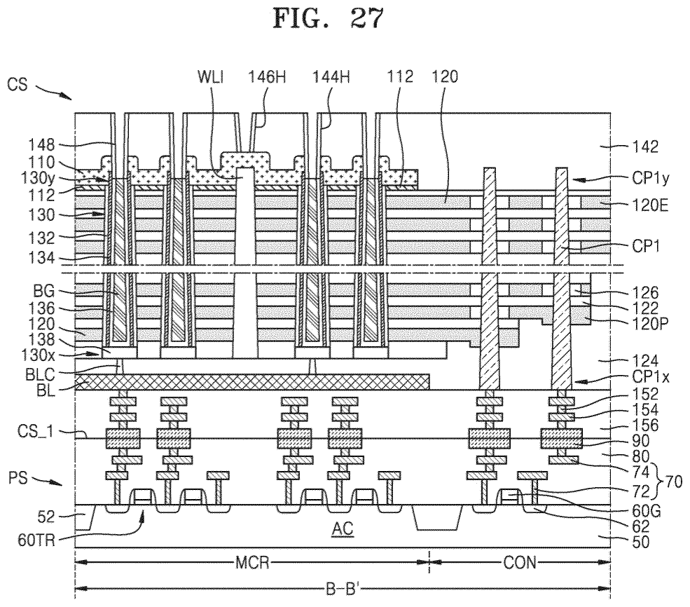

Referring to FIG. 27, a spacer 148 may be formed on sidewalls of the first backside contact hole 144H and the second backside contact hole 146H. In some implementations, the spacer 148 may be arranged on the sidewall of the first backside contact hole 144H, e.g., the spacer 148 may cover sidewalls of the common source layer 110 and the channel layer 134. At least a portion of the upper surface of the back gate electrode BG may be exposed at a bottom portion of the first backside contact hole 144H without being covered by the spacer 148. In addition, the spacer 148 may be arranged on the sidewall of the second backside contact hole 146H, and the upper surface of the common source layer 110 may be exposed at the bottom portion of the second backside contact hole 146H.

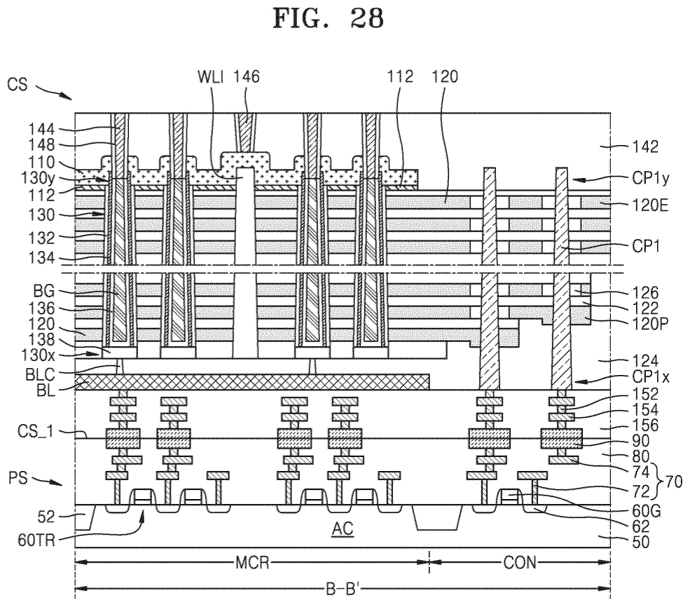

Referring to FIG. 28, a back gate contact 144 and a common source contact 146 may be formed within the first backside contact hole 144H and the second backside contact hole 146H, respectively.

In some implementations, the back gate contact 144 and the common source contact 146 may be formed by forming a conductive layer within the first backside contact hole 144H and the second backside contact hole 146H by using a metal such as tungsten, nickel, cobalt, or tantalum, a metal nitride such as titanium nitride, tantalum nitride, or tungsten nitride, a metal silicide such as tungsten silicide, nickel silicide, cobalt silicide, or tantalum silicide, or a combination thereof and planarizing an upper portion of the conductive layer. Accordingly, the back gate contact 144 and the common source contact 146 may include upper surfaces arranged at the same vertical level as an upper surface of the upper insulating layer 142.

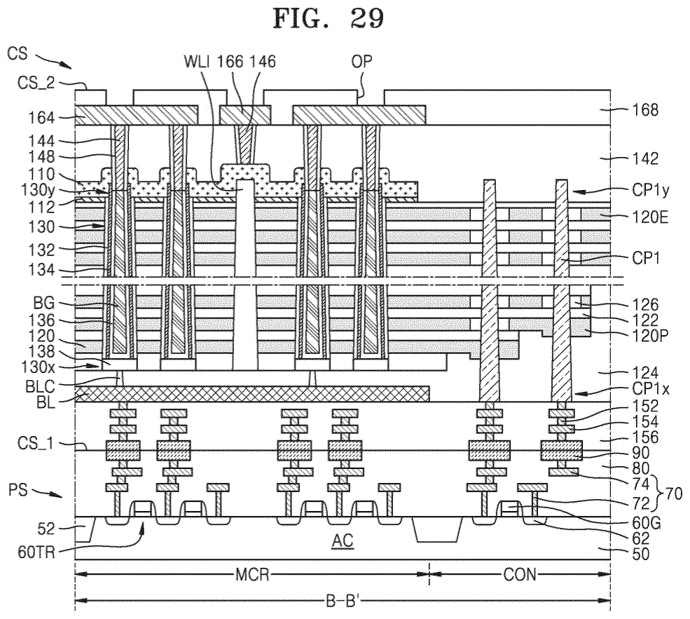

Referring to FIG. 29, a first backside wiring layer 164 and a second backside wiring layer 166 may be formed on the upper insulating layer 142. The first backside wiring layer 164 may be electrically connected to the back gate contact 144, and the second backside wiring layer 166 may be electrically connected to the common source contact 146. For example, the first backside wiring layer 164 and the second backside wiring layer 166 may be spaced apart from each other in a horizontal direction.

Subsequently, a passivation layer 168, which covers the first backside wiring layer 164 and the second backside wiring layer 166, may be formed on the upper insulating layer 142, and an opening OP may be formed in the passivation layer 168 to expose upper surfaces of the first backside wiring layer 164 and the second backside wiring layer 166.

In some implementations, the back gate contact 144 and the first backside wiring layer 164 for providing an electrical connection to the back gate electrode BG, may be provided on a second surface CS_2 of the cell structure CS, and thus, areas and the degrees of freedom of the arrangement of the back gate contact 144 and the first backside wiring layer 164 may be improved. In addition, the back gate contact 144 and the first backside wiring layer 164 may be simultaneously formed in a manufacturing process for forming the common source contact 146 and the second backside wiring layer 166, respectively, and thus, the back gate contact 144 and the first backside wiring layer 164 may be formed without adding a process step.

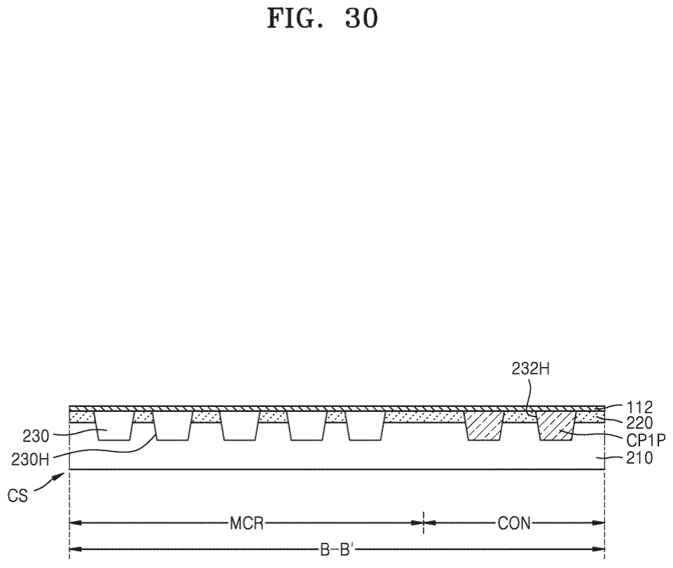

FIGS. 30 to 33 are cross-sectional views illustrating an example of a method of manufacturing the semiconductor device 100B.

Referring to FIG. 30, a buffer insulating layer 220 may be formed on a cell substrate 210, and an opening 230H, and a landing pad opening 232H may be formed by removing portions of the cell substrate 210 and the buffer insulating layer 220. Subsequently, a sacrificial layer 230 may be formed within the opening 230H, and a landing pad portion CP1P may be formed within the landing pad opening 232H.

In some implementations, the sacrificial layer 230 and the landing pad portion CP1P may be formed by using metal such as tungsten, nickel, cobalt, or tantalum, metal nitride such as titanium nitride, tantalum nitride, or tungsten nitride, metal silicide such as tungsten silicide, nickel silicide, cobalt silicide, or tantalum silicide, or a combination thereof. In some implementations, the sacrificial layer 230 and the landing pad portion CP1P may be formed by using the same material, but in some implementations, the sacrificial layer 230 and the landing pad portion CP1P may be formed by using different materials.

Subsequently, an etch stop layer 112, which covers the sacrificial layer 230 and the landing pad portion CP1P, may be formed on the buffer insulating layer 220.

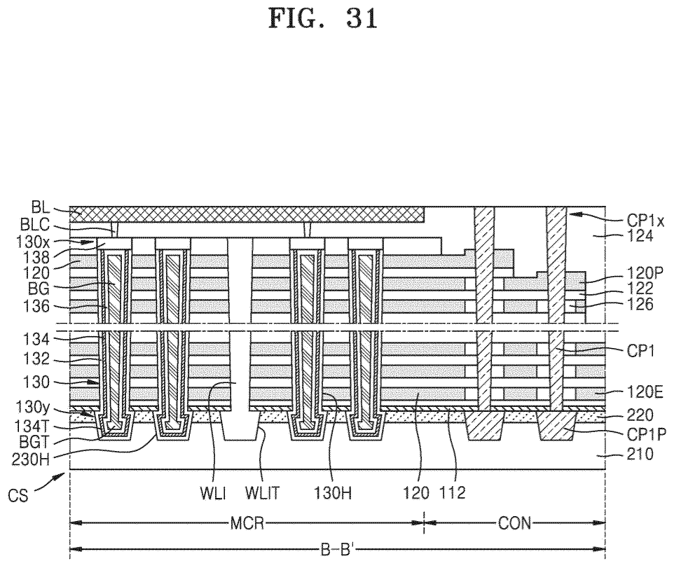

Referring to FIG. 31, gate electrodes 120 and mold insulating layers 122 are alternately formed in a cell region MCR and a connection region CON, and extension portions 120E and a pad portion 120P, which are connected to the gate electrodes 120, may be formed in the connection region CON. In addition, a channel structure 130, which extends in a vertical direction by passing through the gate electrodes 120, and a bit line BL, which is connected to the channel structure 130, may be formed in the cell region MCR.

In some implementations, in the process of forming the channel structure 130, a mold stack, which alternately includes sacrificial layers (not shown) and mold insulating layers 122 on the etch stop layer 112, may be formed in the cell region MCR and the connection region CON, and a channel hole 130H, which passes through the mold stack, may be formed in the cell region MCR. The channel hole 130H may be formed to pass through the etch stop layer 112 and expose an upper surface of the sacrificial layer 230 of FIG. 30 arranged within the opening 230H. Subsequently, the sacrificial layer 230 may be removed, a gate insulating layer 132, a channel layer 134, an insulating liner 136, and a back gate electrode BG may be sequentially formed on an inner wall of the channel hole 130H and an inner wall of the opening 230H, and a drain region 138 may be formed at an entrance of the channel hole 130H.

In some implementations, the opening 230H may be formed to have a greater width in the horizontal direction than the channel hole 130H, and accordingly, a portion of the back gate electrode BG, which is arranged within the opening 230H, may be formed to have a greater width in the horizontal direction than a portion of the back gate electrode BG arranged within the channel hole 130H. Here, a portion of the back gate electrode BG, which is arranged within the opening 230H of the channel hole 130H, may be referred to as an extension portion BGT.

In addition, a first plug CP1, which passes through the extension portions 120E and the pad portion 120P, may be formed in the connection region CON. In some implementations, a first plug hole CP1H, which passes through the mold stack, may be formed in the connection region CON. An upper surface of the landing pad portion CP1P may be exposed at a bottom portion of the first plug hole CP1H. Subsequently, a portion of the sacrificial layer, which is exposed on a sidewall of the first plug hole CP1H, may be removed by lateral etching, and an insulating pattern 126 may be formed in the portion from which the sacrificial layer is removed. Subsequently, the first plug CP1 may be formed within the first plug hole CP1H.

Subsequently, by performing the processes described with reference to FIGS. 18 to 20, the cell structure CS and the peripheral circuit structure PS may be bonded to each other, and the second end portion 130y of the channel structure 130 and the landing pad portion CP1P may be exposed by removing the cell substrate 210.

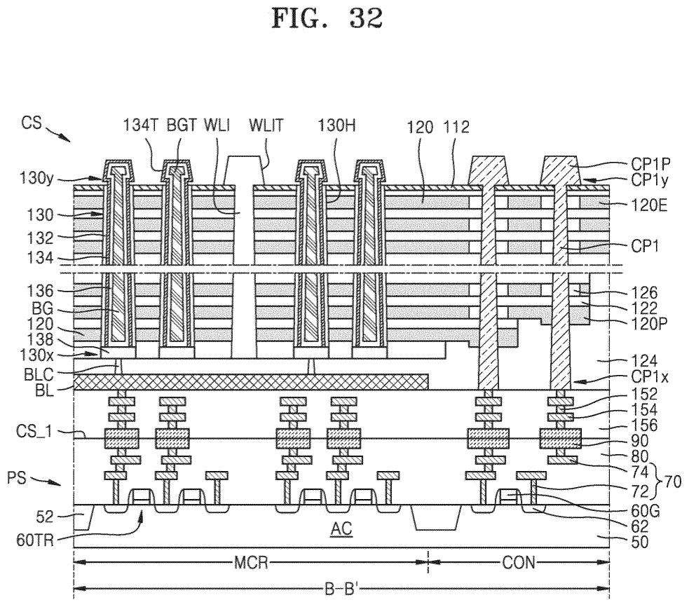

Referring to FIG. 32, an upper surface of the channel layer 134 is exposed by removing a portion of the gate insulating layer 132 exposed at the second end portion 130y of the channel structure 130. The process of removing the gate insulating layer 132 may be performed so that the upper surface of the etch stop layer 112 is exposed in the process of removing the gate insulating layer 132.

In some implementations, an upper side of the gate insulating layer 132 may be removed such that the gate insulating layer 132 is arranged at a lower level than the upper surface of the channel layer 134 and portions of the upper surface and the sidewall of the channel layer 134 are exposed. The gate insulating layer 132 may be removed, and an extension portion 134T of the channel layer 134 may be exposed at a higher vertical level than the etch stop layer 112.

Subsequently, a first backside contact hole 144H and a second backside contact hole 146H, which pass through an upper insulating layer 142, may be formed by performing the processes described with reference to FIGS. 23 to 28.

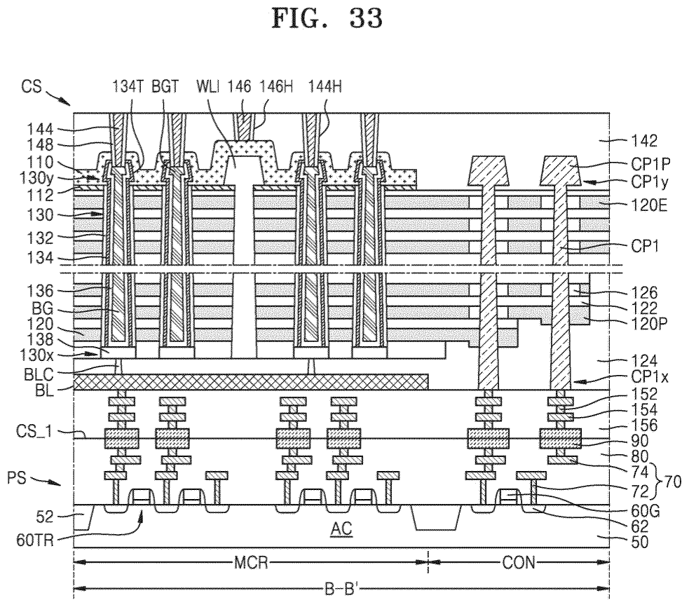

Referring to FIG. 33, a spacer 148 may be formed on inner walls of the first backside contact hole 144H and the second backside contact hole 146H. Subsequently, a back gate contact 144 and a common source contact 146 may be formed within the first backside contact hole 144H and the second backside contact hole 146H, respectively.

Subsequently, the semiconductor device 100B may be completely formed by performing the processes described with reference to FIG. 29.

In some implementations, the extension portion 134T of the channel layer 134 may be arranged at the second end portion 130y of the channel structure 130, and thus, a contact area between the channel layer 134 and the common source layer 110 may increase. In addition, an extension portion BGT of the back gate electrode BG may be arranged at the second end portion 130y of the channel structure 130, and thus, the first backside contact hole 144H may be formed to have a relatively great width, a contact area between the extension portion BGT of the back gate electrode BG and the back gate contact 144 may increase, and/or a misalignment defect in the process of forming the first backside contact hole 144H may be prevented or reduced.

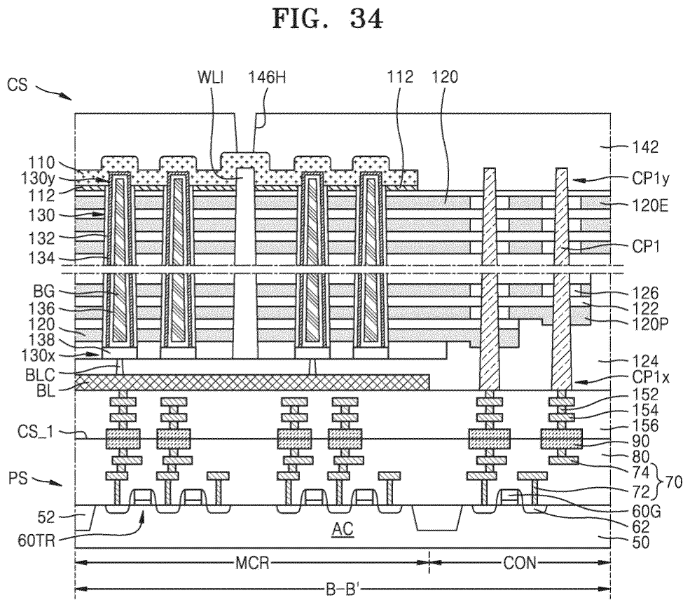

FIGS. 34 to 36 are cross-sectional views illustrating an example of a method of manufacturing the semiconductor device 100D.

An upper insulating layer 142 may be formed on a common source layer 110 by performing the processes described with reference to FIGS. 16 to 25.

Referring to FIG. 34, a second backside contact hole 146H may be formed by removing a portion of the upper insulating layer 142. The common source layer 110 may be exposed at a bottom portion of the second backside contact hole 146H.

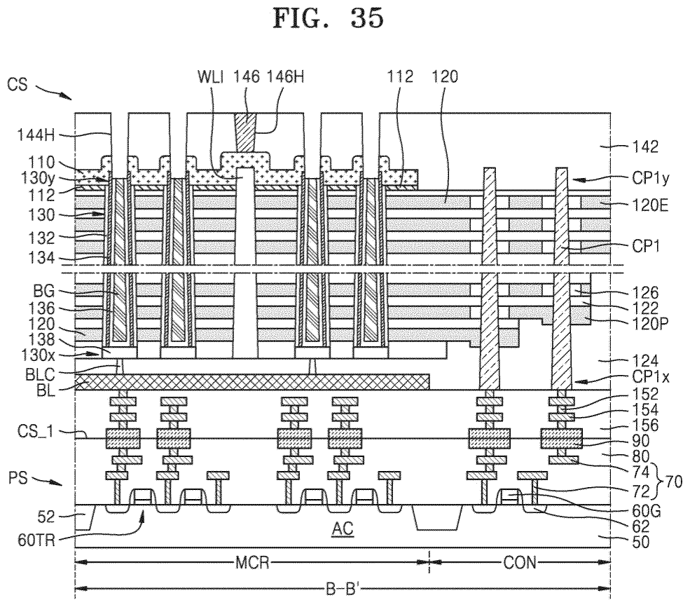

Referring to FIG. 35, a common source contact 146 may be formed on an inner wall of the second backside contact hole 146H.

In some implementations, the common source contact 146 may be formed by using a metal such as tungsten, nickel, cobalt, or tantalum, a metal nitride such as titanium nitride, tantalum nitride, or tungsten nitride, a metal silicide such as tungsten silicide, nickel silicide, cobalt silicide, or tantalum silicide, or a combination thereof.

In some implementations, unlike the manufacturing method described with reference to FIGS. 16 to 29, the spacer 148 may not be formed on the inner wall of the second backside contact hole 146H. Accordingly, the common source contact 146 may be surrounded by the upper insulating layer 142 and may be in contact with the upper insulating layer 142.

Subsequently, a first backside contact hole 144H may be formed by removing a portion of the upper insulating layer 142 and a portion of the common source layer 110. In the process of forming the first backside contact hole 144H, a horizontal extension portion of the channel layer 134, which is arranged at a second end portion 130y of a channel structure 130, may be removed, and then a horizontal extension portion of an insulating liner 136, which is arranged underneath the horizontal extension portion of the channel layer 134, may be removed. After the horizontal extension portion of the channel layer 134 and the horizontal extension portion of the insulating liner 136 are removed, an upper surface of a back gate electrode BG may be exposed at a bottom portion of the first backside contact hole 144H.

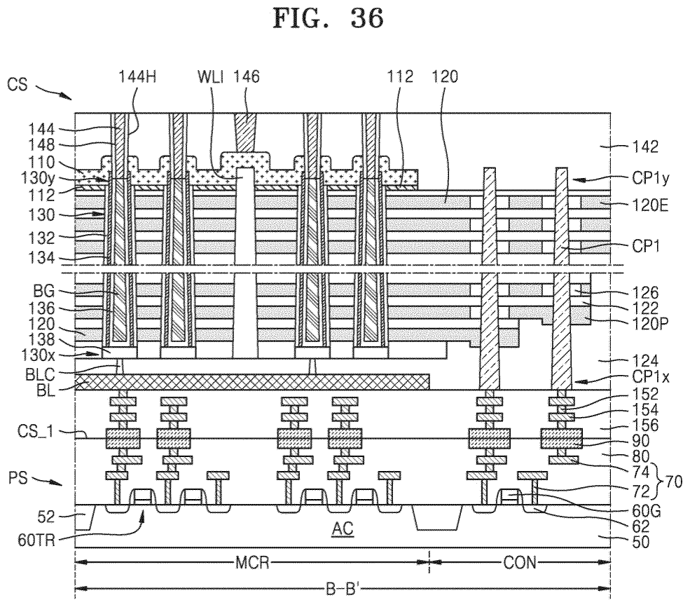

Referring to FIG. 36, the spacer 148 may be formed on a sidewall of the first backside contact hole 144H.

In some implementations, the spacer 148 may be arranged on the sidewall of the first backside contact hole 144H, e.g., the spacer 148 may cover sidewalls of the common source layer 110 and the channel layer 134.

Subsequently, a back gate contact 144 may be formed within the first backside contact hole 144H.

The semiconductor device 100D may be completely formed by performing the above-described process.

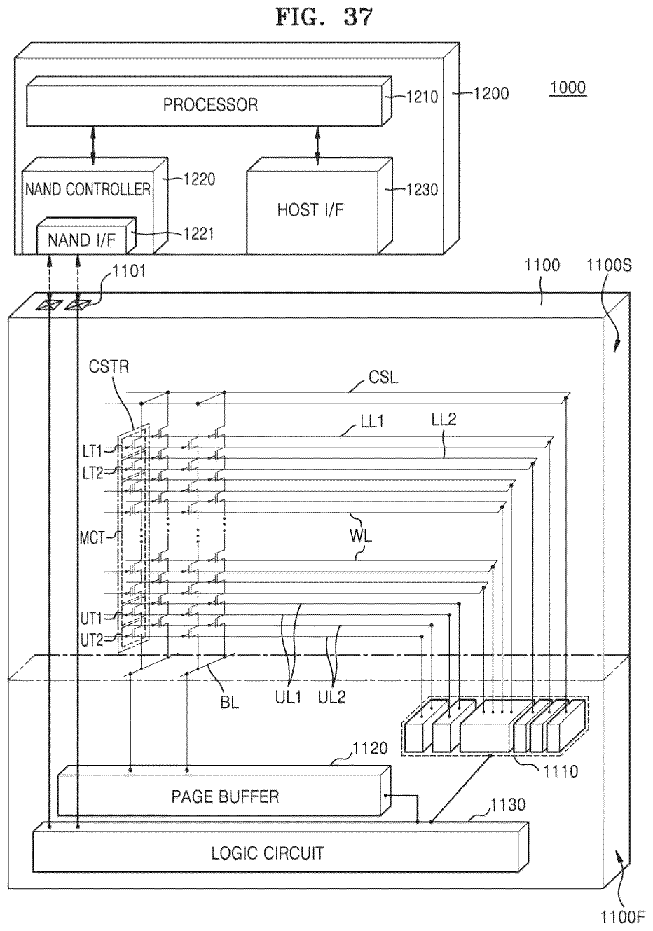

FIG. 37 is a diagram schematically illustrating an example of a data storage system 1000 including a semiconductor device.

Referring to FIG. 37, the data storage system 1000 includes one or more semiconductor devices 1100 and a memory controller 1200 electrically connected to the semiconductor devices 1100. The data storage system 1000 may be, for example, a solid state drive (SSD) device, a universal serial bus (USB), a computing system, a medical device, or a communication device which includes at least one semiconductor device 1100.

The semiconductor device 1100 may be a non-volatile semiconductor device, e.g., the semiconductor device 1100 may be a NAND flash semiconductor device including one of the semiconductor devices 10, 100, 100A, 100B, 100C, and 100D described with reference to FIGS. 1 to 15. The semiconductor device 1100 may include a first structure 1100F and a second structure 1100S on the first structure 1100F. The first structure 1100F may be a peripheral circuit structure including a row decoder 1110, a page buffer 1120, and a logic circuit 1130.

The second structure 1100S may be a memory cell structure including a bit line BL, a common source line CSL, a plurality of word lines WL, first and second string select lines UL1 and UL2, first and second ground select lines LL1 and LL2, and a plurality of memory cell strings CSTR between the bit line BL and the common source line CSL.

In the second structure 1100S, each of the plurality of memory cell strings CSTR may include ground select transistors LT1 and LT2 adjacent to the common source line CSL, string select transistors UT1 and UT2 adjacent to the bit line BL, and a plurality of memory cell transistors MCT arranged between the ground select transistors LT1 and LT2 and the string select transistors UT1 and UT2. The number of ground select transistors LT1 and LT2 and the number of string select transistors UT1 and UT2 may be variously modified.

In some implementations, the plurality of ground select lines LL1 and LL2 may be respectively connected to gate electrodes of the ground select transistors LT1 and LT2. The word line WL may be connected to a gate electrode of the memory cell transistor MCT. The plurality of string select lines UL1 and UL2 may be respectively connected to gate electrodes of the string select transistors UT1 and UT2.

The common source line CSL, the plurality of ground select lines LL1 and LL2, the plurality of word lines WL, and the plurality of string select lines UL1 and UL2 may be connected to the row decoder 1110. The plurality of bit lines BL may be electrically connected to the page buffer 1120.

The semiconductor device 1100 may communicate with the memory controller 1200 through an input/output pad 1101 electrically connected to the logic circuit 1130. The input/output pad 1101 may be electrically connected to the logic circuit 1130.

The memory controller 1200 may include a processor 1210, a NAND controller 1220, and a host interface 1230. In some implementations, the data storage system 1000 may include a plurality of semiconductor devices 1100, and in this case, the memory controller 1200 may control the plurality of semiconductor devices 1100.

The processor 1210 may control an overall operation of the data storage system 1000 including the memory controller 1200. The processor 1210 may operate according to certain firmware and may access the semiconductor device 1100 by controlling the NAND controller 1220. The NAND controller 1220 may include a NAND interface 1221 that processes communication with the semiconductor device 1100. A control command for controlling the semiconductor device 1100, data to be written to the plurality of memory cell transistors MCT of the semiconductor device 1100, data to be read from the plurality of memory cell transistors MCT of the semiconductor device 1100, and the like may be transmitted through the NAND interface 1221. The host interface 1230 may provide a communication function between the data storage system 1000 and an external host. When the control command is received from the external host through the host interface 1230, the processor 1210 may control the semiconductor device 1100 in response to the control command.

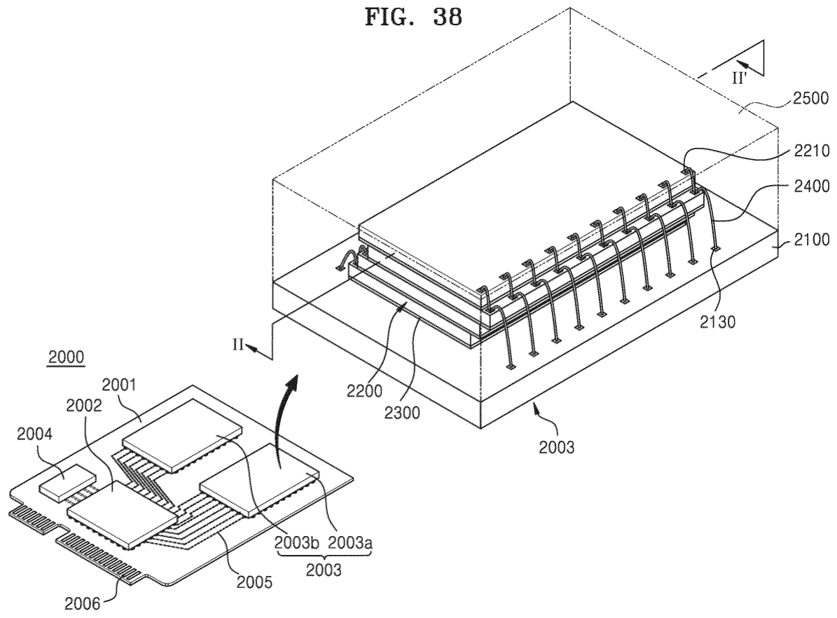

FIG. 38 is a perspective view schematically illustrating an example a data storage system 2000 including a semiconductor device.

Referring to FIG. 38, the data storage system 2000 according to an embodiment may include a main substrate 2001, a memory controller 2002 mounted on the main substrate 2001, one or more semiconductor packages 2003, and dynamic random access memory (DRAM) 2004. The semiconductor package 2003 and the DRAM 2004 may be connected to the memory controller 2002 by a plurality of wiring patterns 2005 formed on the main substrate 2001.

The main substrate 2001 includes a connector 2006 including a plurality of pins coupled to an external host. The number and arrangement of the plurality of pins in the connector 2006 may vary according to a communication interface between the data storage system 2000 and the external host. In some implementations, the data storage system 2000 may communicate with the external host according to any one of interfaces such as a USB, peripheral component interconnect express (PCI-Express), serial advanced technology attachment (SATA), and M-Phy for universal flash storage (UFS). In some implementations, the data storage system 2000 may operate by power supplied from the external host through the connector 2006. The data storage system 2000 may further include a power management integrated circuit (PMIC) that distributes power supplied from the external host to the memory controller 2002 and the semiconductor package 2003.

The memory controller 2002 may write data to the semiconductor package 203 or read data from the semiconductor package 2003, and may improve an operation speed of the data storage system 2000.

The DRAM 2004 may be a buffer memory for alleviating a difference between speeds of the semiconductor package 2003, which is a data storage space, and the external host. The DRAM 2004 included in the data storage system 2000 may operate as a kind of cache memory, and may provide a space for temporarily storing data in a control operation for the semiconductor package 2003. When the data storage system 2000 includes the DRAM 2004, the memory controller 2002 may further include a DRAM controller for controlling the DRAM 2004, in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, a plurality of semiconductor chips 2200 on the package substrate 2100, an adhesive layer 2300 arranged on a lower surface of each of the plurality of semiconductor chips 2200, a connection structure 2400 electrically connecting the plurality of semiconductor chips 2200 to the package substrate 2100, and a molding layer 2500 covering the plurality of semiconductor chips 2200 and the connection structure 2400 on the package substrate 2100.

The package substrate 2100 may be a printed circuit board including a plurality of package upper pads 2130. Each of the plurality of semiconductor chips 2200 may include an input/output pad 2210. The input/output pad 2210 may correspond to the input/output pad 1101 of FIG. 37. Each of the plurality of semiconductor chips 2200 may include at least one of the semiconductor devices 10, 100, 100A, 100B, 100C, and 100D described with reference to FIGS. 1 to 15.

In some implementations, the connection structure 2400 may be a bonding wire electrically connecting the input/output pad 2210 to the package upper pad 2130. Therefore, in the first and second semiconductor packages 2003a and 2003b, the plurality of semiconductor chips 2200 may be electrically connected to one another in a bonding wire method and may be electrically connected to the package upper pad 2130 of the package substrate 2100. In some implementations, in the first and second semiconductor packages 2003a and 2003b, the plurality of semiconductor chips 2200 may be electrically connected to one another by a connection structure including a through silicon via (TSV), instead of the connection structure 2400 in the bonding wire method.

In some implementations, the memory controller 2002 and the plurality of semiconductor chips 2200 may be included in one package. In an embodiment, the memory controller 2002 and the plurality of semiconductor chips 2200 may be mounted on a separate interposer substrate that is different from the main substrate 2001, and the memory controller 2002 and the plurality of semiconductor chips 2200 may be connected to each other by a wire formed on the interposer substrate.

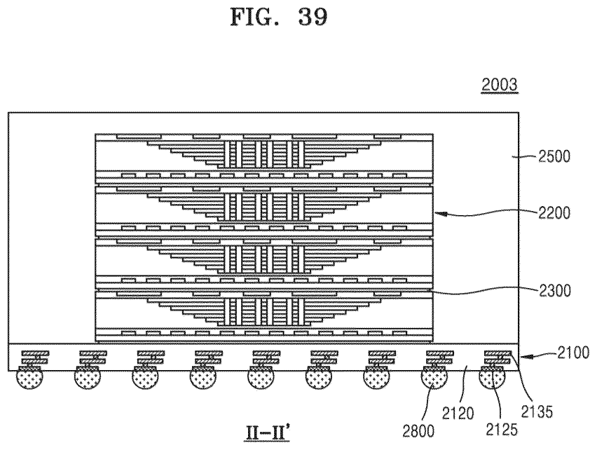

FIG. 39 is a cross-sectional view schematically illustrating an example of a semiconductor package 2003. FIG. 39 is a cross-sectional view taken along line II-II′ of FIG. 38.

Referring to FIG. 39, in the semiconductor package 2003, a package substrate 2100 may be a printed circuit board. The package substrate 2100 includes a package substrate body 2120, a plurality of package upper pads 2130 of FIG. 38 arranged on an upper surface of the package substrate body 2120, a plurality of lower pads 2125 arranged on a lower surface of the package substrate body 2120 or exposed through the lower surface, and a plurality of internal wires 2135 electrically connecting the plurality of package upper pads 2130 of FIG. 38 and the plurality of lower pads 2125 inside the package substrate body 2120. As illustrated in FIG. 38, the plurality of package upper pads 2130 may be electrically connected to a plurality of connection structures 2400. As illustrated in FIG. 38, the plurality of lower pads 2125 may be connected to a plurality of wiring patterns 2005 on the main substrate 2001 of the data storage system 2000 shown in FIG. 38 through a plurality of conductive bumps 2800. Each of the plurality of semiconductor chips 2200 may include at least one of the semiconductor devices 10, 100, 100A, 100B, 100C, and 100D described with reference to FIGS. 1 to 15.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While the inventive concept has been particularly shown and described with reference to embodiments thereof, it will be understood that various changes in form and details may be made therein without departing from the spirit and scope of the following claims.

What is claimed is:

1. A semiconductor device comprising:
a peripheral circuit structure; and
a cell structure stacked on the peripheral circuit structure, wherein the cell structure comprises:
gate electrodes spaced apart from each other in a vertical direction;
a channel structure that is arranged within a channel hole extending through the gate electrodes in the vertical direction, that includes a channel layer and a back gate electrode spaced apart from the channel layer, and that includes a first end portion arranged adjacent to the peripheral circuit structure and a second end portion opposite to the first end portion;
a common source layer connected to the channel layer at the second end portion of the channel structure;
an upper insulating layer disposed on the common source layer; and
a back gate contact that is arranged within a first backside contact hole, that extends through the upper insulating layer and the common source layer, and that is connected to the back gate electrode.

2. The semiconductor device of claim 1, wherein the cell structure further comprises a spacer arranged on an inner wall of the first backside contact hole.

3. The semiconductor device of claim 2, wherein the spacer is located between the back gate contact and the common source layer.

4. The semiconductor device of claim 1, wherein the cell structure further comprises a common source contact that is arranged within a second backside contact hole extending through the upper insulating layer and that is connected to the common source layer, and
wherein an upper surface of the common source contact is arranged at the same level as an upper surface of the back gate contact.

5. The semiconductor device of claim 4, wherein the cell structure further comprises a spacer arranged within the second backside contact hole and surrounding a sidewall of the common source contact.

6. The semiconductor device of claim 4, wherein the cell structure further comprises:
a first backside wiring layer arranged on the upper insulating layer and electrically connected to the back gate contact; and
a second backside wiring layer arranged on the upper insulating layer, spaced apart from the first backside wiring layer, and electrically connected to the common source contact.

7. The semiconductor device of claim 6, wherein the cell structure further comprises a stack isolation insulating layer extending through the gate electrodes in a first horizontal direction,
wherein the second backside wiring layer is arranged at a location vertically overlapping the stack isolation insulating layer, and
wherein the first backside wiring layer is arranged at a location vertically overlapping the channel structure.

8. The semiconductor device of claim 1, wherein the back gate electrode comprises an extension portion at the second end portion of the channel structure, and the back gate contact is arranged on an upper surface of the extension portion of the back gate electrode.

9. The semiconductor device of claim 8, wherein the channel layer comprises an extension portion at the second end portion of the channel structure, and a horizontal width of the extension portion of the channel layer is greater than a horizontal width of a portion of the channel layer surrounded by the gate electrodes.

10. The semiconductor device of claim 1, wherein the cell structure further comprises:
a bit line contact electrically connected to the channel layer at the first end portion of the channel structure; and
a bit line electrically connected to the bit line contact.

11. The semiconductor device of claim 1, wherein the channel structure further comprises:
a gate insulating layer arranged on a sidewall of the channel hole and located between the channel layer and the gate electrodes; and
an insulating liner located between the channel layer and the back gate electrode,
wherein the insulating liner and the gate insulating layer have a cylindrical shape extending in the vertical direction.

12. The semiconductor device of claim 11, wherein the back gate electrode has a pillar shape extending in the vertical direction, and a bottom surface of the back gate electrode is covered by the insulating liner at the first end portion of the channel structure.

13. A semiconductor device comprising:
a peripheral circuit structure; and
a cell structure stacked on the peripheral circuit structure, wherein the cell structure comprises:
gate electrodes spaced apart from each other in a vertical direction;
a channel structure that is arranged within a channel hole extending through the gate electrodes in the vertical direction, that includes a channel layer and a back gate electrode spaced apart from the channel layer, and that includes a first end portion arranged adjacent to the peripheral circuit structure and a second end portion opposite to the first end portion;
a bit line arranged adjacent to the first end portion of the channel structure and electrically connected to the channel layer;
a common source layer disposed adjacent to the second end portion of the channel structure and connected to the channel layer;
a back gate contact disposed adjacent to the second end portion of the channel structure and connected to the back gate electrode; and
a first backside wiring layer disposed on the back gate contact and electrically connected to the back gate contact.

14. The semiconductor device of claim 13, wherein the cell structure further comprises:
an upper insulating layer arranged on the common source layer and surrounding the back gate contact; and
a spacer located between the back gate contact and the upper insulating layer and between the back gate contact and the common source layer.

15. The semiconductor device of claim 14, wherein the cell structure further comprises:
a common source contact extending through the upper insulating layer and connected to the common source layer; and
a second backside wiring layer arranged on the upper insulating layer, spaced apart from the first backside wiring layer, and electrically connected to the common source contact.

16. The semiconductor device of claim 15, wherein an upper surface of the common source contact is arranged at the same level as an upper surface of the upper insulating layer, and an upper surface of the back gate contact is arranged at the same level as the upper surface of the upper insulating layer.

17. The semiconductor device of claim 15, wherein the cell structure further comprises a stack isolation insulating layer extending through the gate electrodes in a first horizontal direction,
wherein the second backside wiring layer is arranged at a location vertically overlapping the stack isolation insulating layer, and
wherein the first backside wiring layer is arranged at a location vertically overlapping the channel structure.

18. A semiconductor device comprising:
a peripheral circuit structure comprising a substrate and a peripheral circuit transistor arranged on the substrate;
gate electrodes spaced apart from each other in a vertical direction on the peripheral circuit structure;
a channel layer arranged within a channel hole extending through the gate electrodes in the vertical direction;
a back gate electrode arranged within the channel hole and electrically insulated from the channel layer by an insulating liner;
a bit line arranged adjacent to a first end portion of the channel layer and electrically connected to the channel layer;
a common source layer arranged adjacent to a second end portion opposite to the first end portion of the channel layer and connected to the channel layer;
an upper insulating layer on the common source layer;
a back gate contact arranged adjacent to the second end portion of the channel layer, the back gate contact extending through the upper insulating layer and the common source layer and connected to the back gate electrode;
a common source contact extending through the upper insulating layer and connected to the common source layer;
a first spacer arranged between the upper insulating layer and the back gate contact and between the common source layer and the back gate contact;
a second spacer arranged between the upper insulating layer and the common source contact;
a first backside wiring layer arranged on the upper insulating layer and electrically connected to the back gate contact; and
a second backside wiring layer spaced apart from the first backside wiring layer on the upper insulating layer and electrically connected to the common source contact.

19. The semiconductor device of claim 18, wherein an upper surface of the common source contact is arranged at the same level as an upper surface of the upper insulating layer, and an upper surface of the back gate contact is arranged at the same level as the upper surface of the upper insulating layer.

20. The semiconductor device of claim 18, further comprising a gate insulating layer arranged on a sidewall of the channel hole and located between the channel layer and the gate electrodes,
wherein the insulating liner is located between the channel layer and the back gate electrode,
wherein the insulating liner and the gate insulating layer have a cylindrical shape extending in the vertical direction,
wherein the back gate electrode has a pillar shape extending in the vertical direction, and
wherein a bottom surface of the back gate electrode arranged adjacent to the first end portion of the channel layer is covered by the insulating liner.
